(19) United States
(12) Patent Application Publication
(10) Pub. No.: US 2024/0228872 A1
(43) Pub. Date: Jul. 11, 2024

(54) NANOPARTICLE-CONTAINING FILM, LIGHT-EMITTING ELEMENT, PRODUCTION METHOD FOR NANOPARTICLE-CONTAINING FILM

(71) Applicant: SHARP KABUSHIKI KAISHA, Sakai City, Osaka (JP)

(72) Inventor: Yuma YAGUCHI, Sakai City, Osaka (JP)

(73) Assignee: SHARP KABUSHIKI KAISHA, Sakai City, Osaka (JP)

(21) Appl. No.: 18/288,656

(22) PCT Filed: Jun. 2, 2021
(86) PCT No.: PCT/JP2021/020963

§ 371 Date: Oct. 27, 2023

(51) Int. Cl. C09K 11/06; H10K 50/115; H10K 71/12; H10K 85/60

(52) U.S. Cl. CPC C09K 11/06; H10K 71/12; H10K 85/60; H10K 50/115

(57) ABSTRACT

A nanoparticle-containing film includes: a plurality of nanoparticles; and a ligand. The ligand is a monomer containing: at least two thiol groups; and a spacer group positioned between the at least two thiol groups, and the spacer group contains: at least one liner chain that bonds the at least two thiol groups together; and at least one branched chain having a sulfide bond, and branched off from the at least one liner chain.

### TECHNICAL FIELD

The present disclosure relates to a nanoparticle-containing film containing a plurality of nanoparticles and ligands, a light-emitting element, and production method for the nanoparticle-containing film.

### BACKGROUND ART

Nanoparticles such as quantum dots are used in various fields such as light-emitting elements, solar cells, and wavelength conversion members. However, nanoparticles such as quantum dots suffer low resistance to air exposure, and a film using these nanoparticles exhibits poor chemical stability. In particular, recent years have seen development of QLEDs (quantum-dot light-emitting diodes) using environment-friendly Cd (cadmium)-free quantum dots, in preparation for mass production of QLED displays. However, such quantum dots particularly suffer low resistance to air exposure, and properties of the quantum dots are significantly degraded by oxygen and water in the atmosphere.

In order to provide the quantum dots with excellent stability against oxygen and water, Patent Document 1 discloses a three dimensional network formed of an oligomer or a polymer containing a thiol group at a terminal thereof. The three dimensional network is formed on, and passivates, the surface of the quantum dots.

In order to produce such quantum dots, Patent Document 1, for example, uses a catalyst to first cause a reaction of a monomer having three or more thiol groups and a monomer having two or more functional groups provided at a terminal of the monomer and capable of reacting with the thiol groups. Thus, the oligomer or the polymer is synthesized in advance as a ligand. After that, the quantum dots are mixed with a solution containing the oligomer or the polymer serving as the ligand, and the thiol groups of the oligomer or the polymer are coordinated with (attached to) the surface of the quantum dots. In Patent Document 1, a solvent containing the quantum dots is applied to form a quantum-dot-containing film.

### CITATION LIST

### Patent Literature

[Patent Document 1] Japanese Patent No. 6,731,954

### SUMMARY OF INVENTION

### Technical Problems

In Patent Document 1, as described above, the oligomer or the polymer is synthesized in advance. After that, the oligomer or the polymer is mixed with the quantum dots.

Thus, in Patent Document 1, the oligomer or the polymer is coordinated with the quantum dots while the thiol groups of the first monomer are randomly capped with the second monomer. Hence, in the method of Patent Document 1, the ligands are coordinated in low density with the quantum dots.

In addition, in the method of Patent Document 1, the oligomer or the polymer is excessive in amount with respect to the quantum dots. When the quantum-dot-containing film containing the quantum dots is incorporated into a device such as a light-emitting element, the excessive amount of polymer or oligomer causes an increase in drive voltage of the device.

An aspect of the present disclosure is conceived in view of the above problem. The present disclosure is set out to provide a nanoparticle-containing film having ligands coordinated in higher density with nanoparticles than a conventional film, having no excessive oligomer or polymer, and exhibiting higher chemical stability against oxygen and water than a conventional film. Furthermore, the present disclosure is set out to provide a light-emitting element including the nanoparticle-containing film, and a method for producing the nanoparticle-containing film.

### Solution to Problems

In order to solve the above problems, a nanoparticle-containing film according to an aspect of the present disclosure includes: a plurality of nanoparticles; and a ligand. The ligand is a monomer containing: at least two thiol groups; and a spacer group positioned between the at least two thiol groups, and the spacer group contains: at least one liner chain that bonds the at least two thiol groups together; and at least one branched chain having a sulfide bond, and branched off from the at least one liner chain.

In order to solve the above problems, a light-emitting element according to an aspect of the present disclosure includes: a first electrode; a second electrode; and the nanoparticle-containing film, according to the present disclosure, disposed between the first electrode and the second electrode.

Moreover, in order to solve the above problems, a production method for nanoparticle-containing film according to an aspect of the present disclosure includes: a nanoparticle film depositing step of depositing a nanoparticle film containing the plurality of nanoparticles, but not containing the ligand; a first monomer supplying step of supplying the nanoparticle film with a first monomer having at least three thiol groups; a second monomer supplying step of supplying, after the first monomer supplying step, the nanoparticle film with a second monomer having one functional group that reacts with a thiol group; and a ligand forming step of forming, after the second monomer supplying step, the ligand by condensation of the first monomer and the second monomer in the nanoparticle film.

### Advantageous Effects of Invention

An aspect of the present disclosure can provide a nanoparticle-containing film having ligands coordinated in higher density with nanoparticles than a conventional film, containing no excessive oligomer or polymer, successfully reducing an increase in drive voltage caused by such excessive oligomer or polymer when the nanoparticle-containing film is incorporated in a device, and exhibiting higher chemical stability against oxygen and water than a conventional film. Furthermore, the present disclosure can provide a light-emitting element including the nanoparticle-containing film, and a method for producing the nanoparticle-containing film.

### BRIEF DESCRIPTION OF DRAWINGS

FIG. 1 is a schematic diagram illustrating a schematic configuration of a nanoparticle-containing film according to a first embodiment.

FIG. 2 is a flowchart showing an example of a production method for the nanoparticle-containing film according to the first embodiment.

FIG. 3 is a diagram schematically illustrating an example of some of the steps of producing the nanoparticle-containing film according to the first embodiment.

FIG. 4 is a diagram schematically illustrating an example of other some of the steps of producing the nanoparticle-containing film according to the first embodiment.

FIG. 5 is a cross-sectional view illustrating an exemplary schematic configuration of a main feature of a display device according to a second embodiment.

FIG. 6 is a schematic view of an example of a light-emitting element according to the second embodiment.

FIG. 7 is a schematic view of an example of a light-emitting element according to a third embodiment.

### DESCRIPTION OF EMBODIMENTS

### First Embodiment

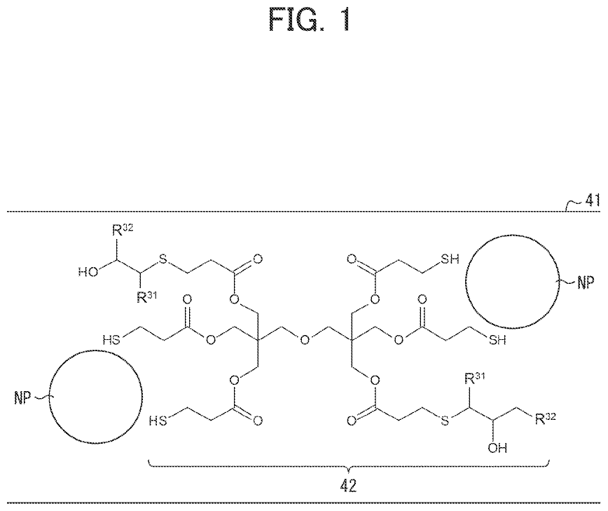

An embodiment of the present disclosure will be described below, with reference to FIGS. 1 to 4. In the description below, the statement “A to B” as to two numbers A and B means “A or more and B or less” unless otherwise specified.

### Nanoparticle-Containing Film

FIG. 1 is a schematic diagram illustrating a schematic configuration of a nanoparticle-containing film 41 according to this embodiment.

As illustrated in FIG. 1, the nanoparticle-containing film 41 according to this embodiment includes: a plurality of nanoparticles NP having a particle size by nano-order (i.e., 1 nm or more and less than 1000 nm); and a ligand 42.

The nanoparticles NP shall not be limited to any particular nanoparticles. Typical nanoparticles NP include quantum dots (hereinafter referred to as “QDs”), or inorganic nanoparticles capable of transporting carriers.

The QDs are inorganic nanoparticles typically having a particle size of several nanometers to several tens of namometers. The QDs are also referred to as semiconductor nanoparticles because a composition of the QDs is derived from a semiconductor material. Furthermore, the QDs are also referred to as nanocrystals because a structure of the QDs is a specific crystal structure. Moreover, the QDs are also referred to as fluorescent nanoparticles or QD phosphor particles because the QDs emit fluorescence and have a size by nano-order. Hence, the QD light-emitting layer is also referred to as a QD phosphor layer.

The QDs may contain a semiconductor material made of at least one element selected from the group consisting of, for example: Cd (cadmium); S (sulfur); Te (tellurium); Se (selenium); Zn (zinc); In (indium); N (nitrogen); P (phosphorus); As (arsenic); Sb (antimony); Al (aluminum); Ga (gallium); Pb (lead); Si (silicon); Ge (germanium); and Mg (magnesium). Note that typical QDs contain Zn. Thus, the QDs may be, for example, a semiconductor material containing Zn atoms.

Each of the QDs may be a core QD, a core-shell QD, or a core-multishell QD. Furthermore, the QD may be a binary-core QD, a tertiary-core QD, or a quaternary-core QD. Note that the QDs may contain doped nanoparticles, or may have a composition-graded structure. An emission wavelength of the QDs can be changed in various manners depending on, for example, the size and the composition of the particles.

Moreover, examples of the nanoparticles capable of transporting carriers include inorganic nanoparticles capable of transporting holes and inorganic nanoparticles capable of transporting electrons. The inorganic nanoparticles capable of transporting the holes are used as a hole transporting-material. The inorganic nanoparticles capable of transporting the electrons are used as an electron-transporting material.

Examples of the inorganic nanoparticles capable of transporting the holes include fine particles made of a p-type semiconductor material. Examples of the p-type semiconductor material include: a metal oxide; a group IV semiconductor; a group II-VI compound semiconductor; a group III-V compound semiconductor; an amorphous semiconductor; and a thiocyanate compound. Examples of the metal oxide include: nickel oxide (NiO); titanium oxide (TiO₂); molybdenum oxide (MoO₂, MoO₃); magnesium oxide (MgO); and nickel lanthanum oxide (LaNiO₃). Examples of the group IV semiconductor include: silicon (Si); and germanium (Ge). Examples of the group II-VI compound semiconductor include: zinc sulfide (ZnS); and zinc selenide (ZnSe). Examples of the group III-V compound semiconductor include: aluminum arsenide (AlAs); gallium arsenide (GaAs); indium arsenide (InAs); aluminum nitride (AlN); gallium nitride (GaN); indium nitride (InN); and gallium phosphide (GaP). Examples of the amorphous semiconductor include: p-type hydrogenated amorphous silicon; and p-type hydrogenated amorphous silicon carbide. Examples of the thiocyanate compound include thiocyanate salts such as copper thiocyanate. These materials may be used alone or in combination of two or more as appropriate.

Furthermore, examples of the inorganic nanoparticles capable of transporting the electrons include fine particles made of an n-type semiconductor material. Examples of the n-type semiconductor material include: a metal oxide; a group II-VI compound semiconductor; a group III-V compound semiconductor; a group IV-IV compound semiconductor; and an amorphous semiconductor. Examples of the metal oxide include: zinc oxide (ZnO), zinc oxide magnesium (ZnMgO); titanium oxide (TiO₂); indium oxide (In₂O₃); tin oxide (SnO, SnO₂); and cerium oxide (CeO₂). Examples of the group II-VI compound semiconductor include: zinc sulfide (ZnS); and zinc selenide (ZnSe). Examples of the group III-V compound semiconductor include: aluminum arsenide (AlAs); gallium arsenide (GaAs); indium arsenide (InAs); aluminum nitride (AlN); gallium nitride (GaN); indium nitride (InN); and gallium phosphide (GaP). Examples of the Group IV-IV compound semiconductor include: silicon germanium (SiGe); and silicon carbide (SIC). Examples of the amorphous semiconductor include n-type hydrogenated amorphous silicon. These materials may be used alone or in combination of two or more as appropriate.

The ligand 42 is a monomer containing: at least two thiol (—SH) groups; and a spacer group 43 positioned between the at least two thiol groups.

The spacer group 43 contains: at least one liner chain that bonds the at least two thiol groups together; and at least one branched chain having a sulfide bond (—S—), and branched off from the at least one liner chain.

The ligand 42 is a monomer obtained by condensation of: at least one first monomer having at least three thiol groups; and at least one second monomer having one functional group that reacts with a thiol group.

The first monomer is a multi-thiol ligand having at least three thiol groups as described above. Examples of the first monomer include a monomer represented by a general formula (1) below.

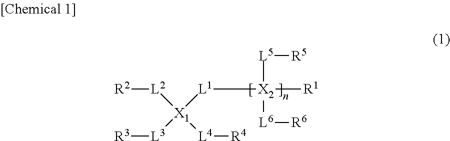

Wherein, in the general formula (1), X¹ and X² each independently represent a carbon atom, a substituted or an unsubstituted arylene group having 6 to 30 carbon atoms, a substituted or an unsubstituted heteroarylene group having 6 to 30 carbon atoms, a substituted or an unsubstituted cycloalkylene group having 3 to 30 carbon atoms, or a substituted or an unsubstituted heterocycloalkyl group having 3 to 30 carbon atoms. Furthermore, L¹ to L⁶ each independently represent either an alkylene group having 1 to 30 carbon atoms, or an alkenylene group having 2 to 30 carbon atoms, in which a single bond, a substituted, or an unsubstituted alkylene group having 1 to 30 carbon atoms, a substituted or an unsubstituted alkenylene group having 2 to 30 carbon atoms, or at least one methylene (—CH₂—) group that is not adjacent to each other is substituted with a substituent selected from a sulfonyl (—S(═O)₂—) group, a carbonyl (—C(═O)—) group, an ether (—O—) group, a sulfide (—S—) group, a sulfoxide (—S(═O)—) group, an ester (—C(═O)O—) group, an amide (—C(═O)NRa—) group, and an imine (—NRb—) group, and a combination thereof. Ra and Rb each independently represent a hydrogen atom or an alkyl group having 1 to 30 carbon atoms. R¹ to R⁶ each independently represent a hydrogen atom, a thiol group, a substituted or an unsubstituted alkyl group having 1 to 30 carbon atoms, a substituted or an unsubstituted aryl group having 6 to 30 carbon atoms, a substituted or an unsubstituted heteroaryl group having 3 to 30 carbon atoms, a substituted or an unsubstituted cycloalkyl group having 3 to 30 carbon atoms, a substituted or an unsubstituted heterocycloalkyl group having 3 to 30 carbon atoms, a substituted or an unsubstituted alkenyl group having 2 to 30 carbon atoms, or a substituted or an unsubstituted alkynyl group having 2 to 30 carbon atoms. Note that n represents an integer of 0 to 2, if n is 0, at least three of R¹ to R⁴ are thiol groups, and if n is 1 or 2, at least three of R¹ to R⁶ are thiol groups.

Note that, in the present disclosure, the term “substitution” means, unless otherwise specified, substitution with at least one substituent selected from the group consisting of: an alkyl group having 1 to 30 carbon atoms; an alkynyl group having 2 to 30 carbon atoms; an aryl group having 6 to 30 carbon atoms; an alkylaryl group having 7 to 30 carbon atoms, an alkoxy group having 1 to 30 carbon atoms; a heteroalkyl group having 1 to 30 carbon atoms; a heteroalkylaryl group having 3 to 30 carbon atoms; a cycloalkyl group having 3 to 30 carbon atoms; a cycloalkenyl group having 3 to 15 carbon atoms; a cycloalkynyl group having 6 to 30 carbon atoms; a heterocycloalkyl group having 2 to 30 carbon atoms; a halogen (—F, —Cl, —Br, or —I); a hydroxy (—OH) group; a nitro (—NO₂) group; a cyano (—CN) group; an amino group (—NRR′ group; wherein R and R′ each independently represent a hydrogen atom or an alkyl group having 1 to 6 carbon atoms), an azido (—N₃) group; an amidino (—C(═NH) NH₂) group; a hydrazino (—NHNH₂) group; a hydrazono (═N (NH₂) group; an aldehyde (—C(═O) H) group; a carbamoyl (—C(═O) NH₂) group; a thiol (—SH) group; an ester group (—C(═O) OR″ group; wherein R″ represents an alkyl group having 1 to 6 carbon atoms or an aryl group having 6 to 12 carbon atoms); a carboxy (—COOH) group or a salt of the carboxy group; a sulfonic acid group (—SO₃H group) or a salt of the sulfonic acid (—SO₃M; wherein M represents an organic cation or an inorganic cation); a phosphoric acid group (—PO₃H₂ group) or a salt of the phosphoric acid group (—PO₃MH or —PO₃M₂; wherein M represents an organic cation or an inorganic cation); a (meth) acryloyloxy group; and a combination thereof.

Furthermore, unless otherwise specified, the term “hetero” means at least one hetero element selected from the group consisting of N, O, S, Si, P, C(═O), S(═O) and S(═O); in a ring, or 1 to 4 functional groups containing the at least one hetero element. Note that, in this case, the ring may be a 3- to 10-membered ring.

Examples of the first monomer include: dipentaerythritol hexakis (3-mercaptopropionate) (DPMP) represented by a structural formula (1a) below; trimethylolpropane tris (3-mercaptopropionate) (TMMP) represented by a structural formula (1b) below; dipentaerythritol hexakis (3-mercaptopropionate) (DHM) represented by a structural formula (1c) below; pentaerythritol tetrakis (3-mercaptopropionate) (DHM) represented by a structural formula (1d) below; pentaerythritol tetrakis (3-mercaptopropionate) represented by a structural formula (1e) below; trimethylolpropane tris (3-mercaptoacetate) represented by a structural formula (1f) below; and tris[2-(3-mercaptopropionyloxy) ethyl]isocyanurate represented by a structural formula (1g) below. These first monomers may be used alone, or in combination of two or more as appropriate.

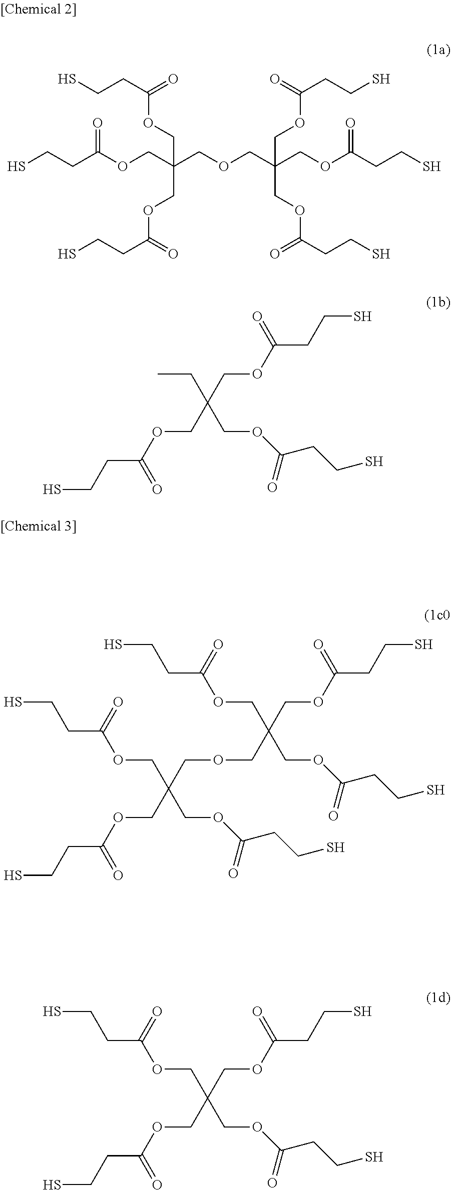 [SMILES: O=C(CCS)OCC(COCC(COC(=O)CCS)(COC(=O)CCS)COC(=O)CCS)(COC(=O)CCS)COC(=O)CCS ; CCC(COC(=O)CCS)(COC(=O)CCS)COC(=O)CCS ; O=C(CCS)OCC(COCC(COC(=O)CCS)(COC(=O)CCS)COC(=O)CCS)(COC(=O)CCS)COC(=O)CCS ; O=C(CCS)OCC(COC(=O)CCS)(COC(=O)CCS)COC(=O)CCS]

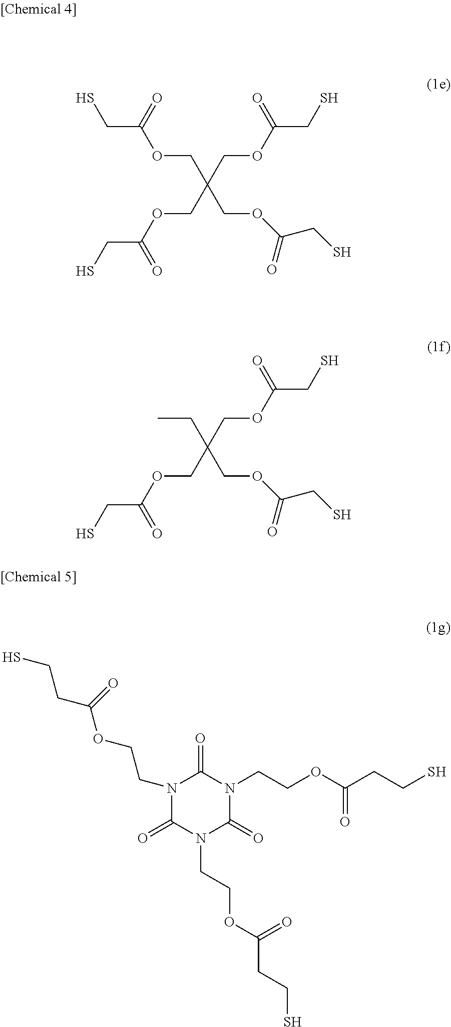 [SMILES: O=C(CS)OCC(COC(=O)CS)(COC(=O)CS)COC(=O)CS ; CCC(COC(=O)CS)(COC(=O)CS)COC(=O)CS ; O=C(CCS)OCCn1c(=O)n(CCOC(=O)CCS)c(=O)n(CCOC(=O)CCS)c1=O]

Examples of the functional group which reacts with a thiol group include an epoxy group, a nitrile group, and an oxazoline group. These functional groups are thiol-labile groups that readily react with thiol groups. Hence, examples of the second monomer include a monomer having any one functional group selected from the group consisting of: an epoxy group; a nitrile group; and an oxazoline group. Note that these second monomers may be used alone, or in combination of two or more as appropriate.

Thus, examples of these second monomers may include: an epoxy-based compound having an epoxy group; a nitrile-based compound having a nitrile group; and an oxazoline-based compound having an oxazoline group. Hence, examples of the second monomers include at least one monomer selected from the group consisting of: the epoxy-based compound; the nitrile-based compound; and the oxazoline-based compound.

Examples of the epoxy-based compound include monoepoxy-based compounds such as: 2-phenylpropylene oxide represented by a structural formula (A1) below; 1,2-epoxyhexane represented by a structural formula (A2) below; 1,3-diphenyl-2,3-epoxy-1-propanone represented by a structural formula (A3) below; benzyl glycidyl ether represented by a structural formula (A4) below; trans-stilbene oxide represented by a structural formula (A5) below; and 1,2-epoxydecane represented by a structural formula (A6) below.

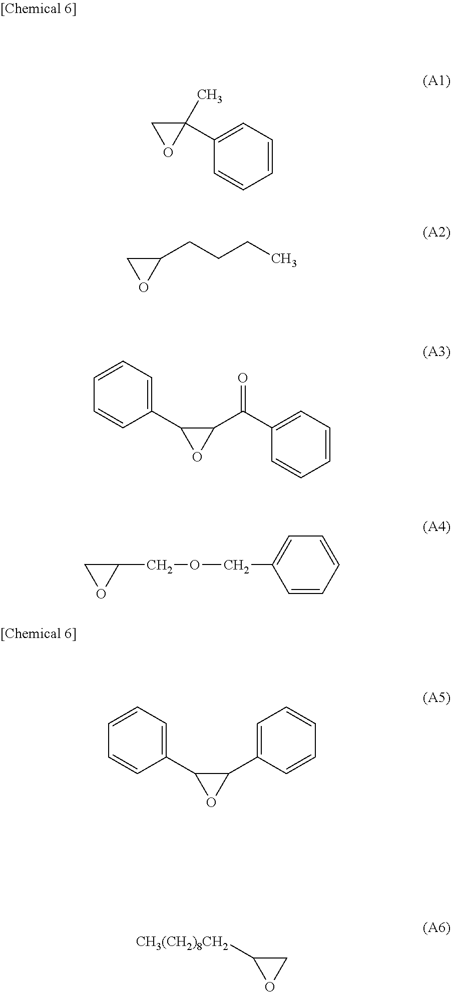

Furthermore, examples of the nitrile-based compound include: 3,5-dimethyl-4-methoxybenzonitrile represented by a structural formula (B1) below; 4-formylbenzonitrile represented by a structural formula (B2) below; isobutyronitrile represented by a structural formula (B3) below, trimethylacetonitrile represented by a structural formula (B4) below; and butyronitrile represented by a structural formula (B5) below.

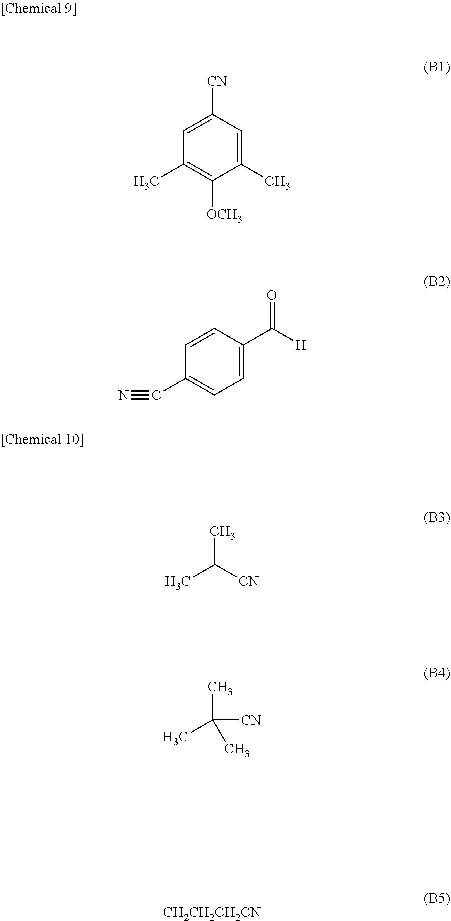

Moreover, examples of the oxazoline-based compound include: 2-phenyl-2-oxazoline represented by a structural formula (C1) below; and 4,4-dimethyl-2-phenyl-2-oxazoline represented by a structural formula (C2) below.

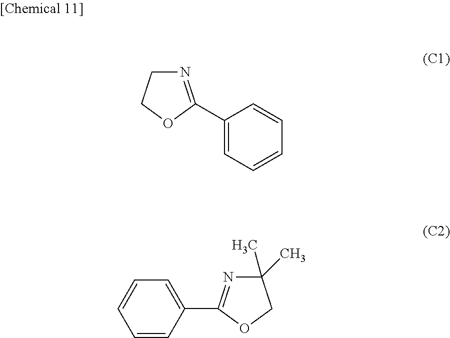

As can be seen, this embodiment uses, as the first monomer, at least one monomer having at least three thiol groups, and, as the second monomer, at least one monomer having one functional group that reacts with a thiol group. Because these monomers are used as the first monomer and the second monomer, some of the thiol groups that the first monomer has can be capped with the second monomer. Such a feature can improve chemical stability of the nanoparticle-containing film against oxygen and water.

Furthermore, as described above, the second monomer is a monomer having one functional group that reacts with a thiol group. Such a feature allows the second monomer to keep the first monomers from linking (crosslinking) themselves.

Moreover, the ligand 42 is a monomer obtained by condensation of: one of the first monomers having at least four thiol groups; and at least two of the second monomers. In this case, the number of capping portions increases, thereby making it possible to further enhance the chemical stability of the nanoparticle-containing film against oxygen and water.

Examples of the ligand 42 include a monomer represented by a general formula (2) below.

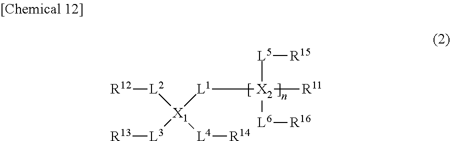

Wherein, in the general formula (2), X¹ and X², as X¹ and X² in the general formula (1), each independently represent a carbon atom, a substituted or an unsubstituted arylene group having 6 to 30 carbon atoms, a substituted or an unsubstituted heteroarylene group having 6 to 30 carbon atoms, a substituted or an unsubstituted cycloalkylene group having 3 to 30 carbon atoms, or a substituted or an unsubstituted heterocycloalkyl group having 3 to 30 carbon atoms. Likewise, L¹ to L⁶, as L¹ to L⁶ in the general formula (1), each independently represent either an alkylene group having 1 to 30 carbon atoms, or an alkenylene group having 2 to 30 carbon atoms, in which a single bond, a substituted, or an unsubstituted alkylene group having 1 to 30 carbon atoms, a substituted or an unsubstituted alkenylene group having 2 to 30 carbon atoms, or at least one methylene group that is not adjacent to each other is substituted with a substituent selected from a sulfonyl group, a carbonyl group, an ether group, a sulfide group, a sulfoxide group, an ester group, an amide (—C(═O)NRa—) group, an imine (—NRb—) group, and a combination thereof. Ra and Rb each independently represent a hydrogen atom or an alkyl group having 1 to 30 carbon atoms.

Furthermore, in the general formula (2), R¹¹ to R¹⁶ each independently represent a hydrogen atom, a thiol group, a substituted or an unsubstituted alkyl group having 1 to 30 carbon atoms, a substituted or an unsubstituted aryl group having 6 to 30 carbon atoms, a substituted or an unsubstituted heteroaryl group having 3 to 30 carbon atoms, a substituted or an unsubstituted cycloalkyl group having 3 to 30 carbon atoms, a substituted or an unsubstituted heterocycloalkyl group having 3 to 30 carbon atoms, a substituted or unsubstituted alkenyl group having 2 to 30 carbon atoms, a substituted or unsubstituted alkynyl group having 2 to 30 carbon atoms, a substituted or an unsubstituted alkyl group bonded through a sulfide bond and having 1 to 30 carbon atoms, a substituted or an unsubstituted aryl group bonded through a sulfide bond and having 6 to 30 carbon atoms, a substituted or an unsubstituted heteroaryl group bonded through a sulfide bond and having 3 to 30 carbon atoms, a substituted or unsubstituted cycloalkyl group bonded through a sulfide bond and having 3 to 30 carbon atoms, a substituted or an unsubstituted hererocycloalkyl group bonded through a sulfide bond and having 3 to 30 carbon atoms, a substituted or an unsubstituted alkenyl group bonded through a sulfide bond and having 2 to 30 carbon atoms, or a substituted or an unsubstituted alkynyl group bonded through a sulfide bond and having 2 to 30 carbon atoms.

Moreover, n represents an integer of 0 to 2. Note that, if n is 0, at least three of R¹¹ to R¹⁴ are thiol groups, and at least one of R¹¹ to R¹⁴ is a substituted or an unsubstituted alkyl group bonded through a sulfide bond and having 1 to 30 carbon atoms, a substituted or unsubstituted aryl group bonded through a sulfide bond and having 6 to 30 carbon atoms, a substituted or an unsubstituted heteroaryl group bonded through a sulfide bond and having 3 to 30 carbon atoms, a substituted or an unsubstituted cycloalkyl group bonded through a sulfide bond and having 3 to 30 carbon atoms, a substituted or an unsubstituted hererocycloalkyl group bonded through a sulfide bond and having 3 to 30 carbon atoms, a substituted or an unsubstituted alkenyl group bonded through a sulfide bond and having 2 to 30 carbon atoms, or a substituted or an unsubstituted alkynyl group bonded through a sulfide bond and having 2 to 30 carbon atoms. If n is 1 or 2, at least two of R¹¹ to R¹⁶ are thiol groups, and at least one of R¹¹ to R¹⁶ is a substituted or an unsubstituted alkyl group bonded through a sulfide bond and having 1 to 30 carbon atoms, a substituted or an unsubstituted aryl group bonded through a sulfide bond and having 6 to 30 carbon atoms, a substituted or an unsubstituted heteroaryl group bonded through a sulfide bond and having 3 to 30 carbon atoms, a substituted or an unsubstituted cycloalkyl group bonded through a sulfide bond and having 3 to 30 carbon atoms, a substituted or an unsubstituted hererocycloalkyl group bonded through a sulfide bond and having 3 to 30 carbon atoms, a substituted or an unsubstituted alkenyl group bonded through a sulfide bond and having 2 to 30 carbon atoms, or a substituted or an unsubstituted alkynyl group bonded through a sulfide bond and having 2 to 30 carbon atoms.

The ligand 42 such as the above ligands can exhibit high chemical stability against oxygen and water, and enhance efficiency in injecting charges into the nanoparticles NP, and, when used as a light-emitting layer, or a carrier transport layer, of a light-emitting element, the nanoparticle-containing film 41 can enhance light emission efficiency of the light-emitting element.

Furthermore, examples of the ligand 42 include a monomer represented by a general formula (3) below.

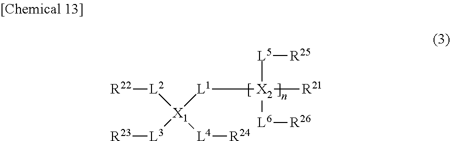

Wherein, in the general formula (3), X¹ and X², as X¹ and X² in the general formula (1), each independently represent a carbon atom, a substituted or an unsubstituted arylene group having 6 to 30 carbon atoms, a substituted or an unsubstituted heteroarylene group having 6 to 30 carbon atoms, a substituted or an unsubstituted cycloalkylene group having 3 to 30 carbon atoms, or a substituted or an unsubstituted heterocycloalkyl group having 3 to 30 carbon atoms. Likewise, L¹ to L⁶, as L¹ to L⁶ in the general formula (1), each independently represent either an alkylene group having 1 to 30 carbon atoms, or an alkenylene group having 2 to 30 carbon atoms, in which a single bond, a substituted, or an unsubstituted alkylene group having 1 to 30 carbon atoms, a substituted or an unsubstituted alkenylene group having 2 to 30 carbon atoms, or at least one methylene group that is not adjacent to each other is substituted with a substituent selected from a sulfonyl group, a carbonyl group, an ether group, a sulfide group, a sulfoxide group, an ester group, an amide (—C(═O) NRa—) group, and an imine (—NRb—) group, and a combination thereof. Ra and Rb each independently represent a hydrogen atom or an alkyl group having 1 to 30 carbon atoms.

Furthermore, wherein, in the general formula (3), R²¹ to R²⁶ each independently represent a hydrogen atom, a thiol group, a substituted or an unsubstituted alkyl group having 1 to 30 carbon atoms, a substituted or an unsubstituted aryl group having 6 to 30 carbon atoms, a substituted or an unsubstituted heteroaryl group having 3 to 30 carbon atoms, a substituted or an unsubstituted cycloalkyl group having 3 to 30 carbon atoms, a substituted or an unsubstituted heterocycloalkyl group having 3 to 30 carbon atoms, a substituted or an unsubstituted alkenyl group having 2 to 30 carbon atoms, a substituted or an unsubstituted alkynyl group having 2 to 30 carbon atoms, an epoxy-based compound residue bonded through a sulfide bond, an oxazoline-based compound residue bonded through a sulfide bond, or a nitrile-based compound residue bonded through a sulfide bond.

Moreover, n represents an integer of 0 to 2. Note that if n is 0, at least three of R²¹ to R²⁴ are thiol groups, and at least one of R²¹ to R²⁴ is an epoxy-based compound residue bonded through a sulfide bond, an oxazoline-based compound residue bonded through a sulfide bond, or a nitrile-based compound residue bonded through a sulfide bond. If n is 1 or 2, at least two of R²¹ to R²⁰ are thiol groups, and at least one of R²¹ to R²⁶ is an epoxy-based compound residue bonded through a sulfide bond, an oxazoline-based compound residue bonded through a sulfide bond, or a nitrile-based compound residue bonded through a sulfide bond.

In this case, too, the ligand 42 such as the above ligands can exhibit high chemical stability against oxygen and water, and enhance efficiency in injecting charges into the nanoparticles NP. In addition, when used as a light-emitting layer, or a carrier transport layer, of a light-emitting element, the nanoparticle-containing film 41 can enhance light emission efficiency of the light-emitting element.

Note that, in the present disclosure, the epoxy-based compound residue bonded through a sulfide bond represents a structure formed by a reaction of a thiol group and an epoxy-based compound. More specifically, the epoxy-based compound residue bonded through a sulfide bond represents, for example, a structure including a sulfide bond and a hydroxy group formed when a thiol group and an epoxy-based compound react together and the epoxy-based compound cleaves (opens).

Wherein, in the general formula (3), if n is 0, at least one of R²¹ to R²⁴ is an epoxy-based compound residue bonded through a sulfide bond, or an oxazoline-based compound residue bonded through a sulfide bond. The at least one of R²¹ to R²⁴ preferably contains: a sulfide bond; and either a hydroxy group, or an amide group. Moreover, wherein, in the general formula (3), if n is 1 or 2, at least one of R²¹ to R²⁶ is an epoxy-based compound residue bonded through a sulfide bond, or an oxazoline-based compound residue bonded through a sulfide bond. The at least one of one of R²¹ to R²⁶ preferably contains: a sulfide bond; and either a hydroxy group, or an amide group.

Examples of the epoxy-based compound residue bonded through the sulfide bond include a group represented by a general formula (4) below.

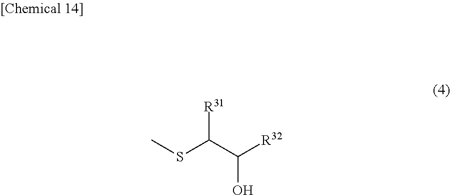

Note that, wherein, in the general formula (4), R³¹ and R³² each independently represent a hydrogen atom or a monovalent organic residue.

The organic residue shall not be limited to a particular organic residue. Desirably, the organic residue does not have a thiol-labile group so as to become a monomer after the reaction (i.e., so as not to become an oligomer or a polymer). Examples of the organic residue include: a substituted or an unsubstituted linear-chain, branched-chain, or cyclic alkyl group having 1 to 20 carbon atoms; and a substituted or an unsubstituted aromatic group having 6 to 20 carbon atoms. If the number of carbon atoms exceeds 20, a slight decrease in light emission characteristics might begins to appear. Hence, the number of carbon atoms is preferably, for example, 20 or less. Note that examples of a substituent include the above exemplary substituents.

Furthermore, at least one methylene group that is not adjacent to each other may be substituted with, for example, a carbonyl group or an ether group.

Examples of the epoxy-based compound residue include epoxy-based compound residues derived from the above exemplary epoxy-based compounds.

Moreover, in the present disclosure, the oxazoline-based compound residue bonded through a sulfide bond represents a structure formed by a reaction of a thiol group and an oxazoline-based compound. More specifically, the oxazoline-based compound residue bonded through a sulfide bond represents, for example, a structure including a sulfide bond and an amid group that are formed when a thiol group and an oxazoline-based compound react together and the oxazoline-based compound cleaves (opens).

Examples of the oxazoline-based compound residue bonded through the sulfide bond include a group represented by a general formula (5) below.

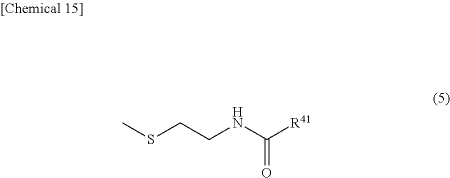

Note that, wherein, in the general formula (5), R⁴¹ represents a hydrogen atom or a monovalent organic residue.

The monovalent organic residue represented by R³¹ or R³² in the general formula (4) and the monovalent organic residue represented by R⁴¹ in the general formula (5) shall not be limited to particular organic residues. However, none of the monovalent organic residues represented by R³¹, R³², or R⁴¹ desirably has a thiol-labile group that readily reacts with a thiol group so as to become a monomer after reaction (i.e., so as not to become an oligomer or a polymer). Examples of the monovalent organic residues include: a substituted or an unsubstituted linear-chain, branched-chain, or cyclic alkyl group having 1 to 20 carbon atoms; and a substituted or an unsubstituted aromatic group having 6 to 20 carbon atoms. In this case, too, if the number of carbon atoms exceeds 20, a slight decrease in light emission characteristics might begins to appear. Hence, the number of carbons is preferably, for example, 20 or less. Note that examples of a substituent include the above exemplary substituents.

Furthermore, the at least one methylene group that is not adjacent to each other may be substituted with a bivalent substituent selected from, for example, a sulfonyl (—S(═O)₂—) group, a carbonyl (—C(═O)—) group, an ether (—O—) group, a sulfide (—S—) group, a sulfoxide (—S(═O)—) group, an ester (—C(═O)O—) group, an amide (—C(═O) NRa—) group, and an imine (—NRb—) group, and a combination thereof. Note that, in this case, too, Ra and Rb each independently represent a hydrogen atom or an alkyl group having 1 to 30 carbon atoms. Moreover, a hydrogen atom (—H) may be substituted with a monovalent substituent other than a thiol group and a thiol-labile group (for example, the above exemplary substituents other than these substituents).

Examples of the oxazoline-based compound residue include oxazoline-based compound residues derived from the above exemplary oxazoline-based compounds.

Furthermore, the nitrile-based compound residue bonded through a sulfide bond represents a structure formed by a reaction of a thiol group and a nitrile-based compound.

Examples of the nitrile-based compound residue include nitrile-based compound residues derived from the above exemplary epoxy-based compounds.

FIG. 1 illustrates an exemplary case where the nanoparticle-containing film 41 contains, as the ligand 42, a ligand represented by a reaction formula (I) below and obtained by condensation of DPMP and an epoxy-based compound.

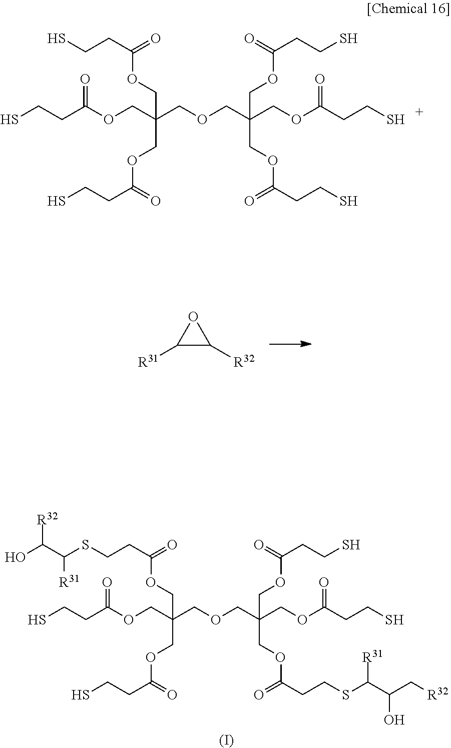

Note that, wherein in the reaction formula (I) and FIGS. 1, R³¹ and R³² each independently represent a hydrogen atom or a monovalent organic residue. Examples of the above epoxy-based compound include the above exemplary epoxy-based compounds.

However, the ligand 42 according to this embodiment shall not be limited to the exemplary ligand illustrated in FIG. 1. For example, the nanoparticle-containing film 41 may contain, as the ligand 42, a ligand represented by a reaction formula (II) below instead of the ligand illustrated in FIG. 1. The ligand may be obtained by condensation of DPMP and an oxazoline-based compound.

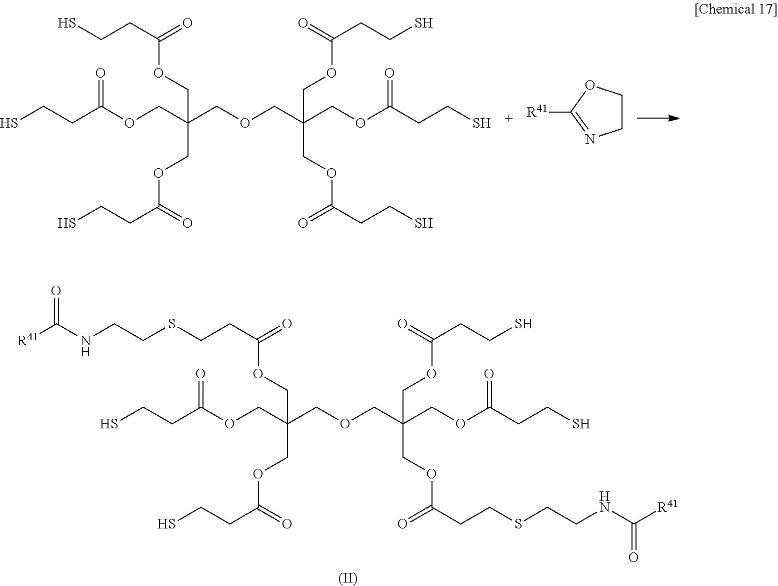

Note that, wherein in the reaction formula (II), R⁴¹ represents a hydrogen atom or a monovalent organic residue, as described above. Examples of the above epoxy-based compound include the above exemplary epoxy-based compounds.

Moreover, in this embodiment, the second monomer is desirably a π-conjugated compound further having a π-conjugated functional group having a π-conjugated electron pair in addition to a functional group that reacts with a thiol group (specifically, for example, the thiol-labile group).

The π-conjugated functional group shall not be limited to a particular π-conjugated functional group. Examples of the π-conjugated functional group include at least one functional group selected from the group consisting of: an aryl group consisting of any one of a 5-membered ring, a 6-membered ring, and a 7-membered ring; a fused ring (a condensed ring) of the aryl group; a derivative of the aryl group; a derivative of the fused ring of the aryl group; a heteroaryl group consisting of any one of a 5-membered ring, a 6-membered ring, and a 7-membered ring, and containing 1 to 3 heteroatoms of at least one kind selected from the group consisting of nitrogen, sulfur, oxygen, and boron; a fused ring of the heteroaryl group; a derivative of the heteroaryl group; and a derivative of the fused ring of the heteroaryl group. Here, the aryl group refers to an aryl group consisting of any one of a 5-membered ring, a 6-membered ring, and a 7-membered ring. Furthermore, the heteroaryl group refers to a heteroaryl group consisting of any one of a 5-membered ring, a 6-membered ring, and a 7-membered ring, and containing 1 to 3 heteroatoms of at least one kind selected from the group consisting of nitrogen, sulfur, oxygen, and boron. Examples of the heteroaryl group include: a nitrogen-containing heteroaryl group; a sulfur-containing heteroaryl group; an oxygen-containing heteroaryl group; and a boron-containing heteroaryl group. In the nitrogen-containing heteroaryl group, the sulfur-containing heteroaryl group, the oxygen-containing heteroaryl group, and the boron-containing heteroaryl group, at least one of a methine (—CH═) group or a vinylene (—CH═CH—) group contained in the aryl group may be substituted with 1 to 3 nitrogen atoms, sulfur atoms, oxygen atoms, or boron atoms.

According to this embodiment, as described above, a π-conjugated system can be provided to the ligand 42 by a second monomer species. More specifically, according to this embodiment, as described above, the π-conjugated compound is used as the second monomer, such that the π-conjugated compound can be bonded as a functional molecule to some of the thiol groups that the first monomer has. Such a feature can enhance efficiency in injecting charges into the nanoparticles NP. Hence, when the nanoparticle-containing film 41 is used as, for example, a light-emitting layer or a carrier transport layer in a light-emitting element, light emission efficiency of the light-emitting element can be improved.

Note that the ligand 42 in the nanoparticle-containing film 41 can be detected by, for example, an MS/MS spectrum of a time-of-flight secondary ion mass spectrometry (TOF-SIMS) apparatus equipped with a tandem mass spectrometer (MS/MS). When the TOF-SIMS apparatus is used to carry out tandem mass spectrometry of the nanoparticle-containing film 41, the structure of molecules in a nano-order thin-film can be analyzed, thereby making it possible to determine with high precision a molecular structure of the ligand 42 contained in the nanoparticle-containing film 41.

Furthermore, as illustrated in FIG. 1, in the nanoparticle-containing film 41, a single ligand 42 is coordinated with desirably at least two nanoparticles NP. In this case, at least two nanoparticle NPs are linked together through a single ligand 42. Such a feature can further enhance the chemical stability of the nanoparticle-containing film 41 against oxygen and water.

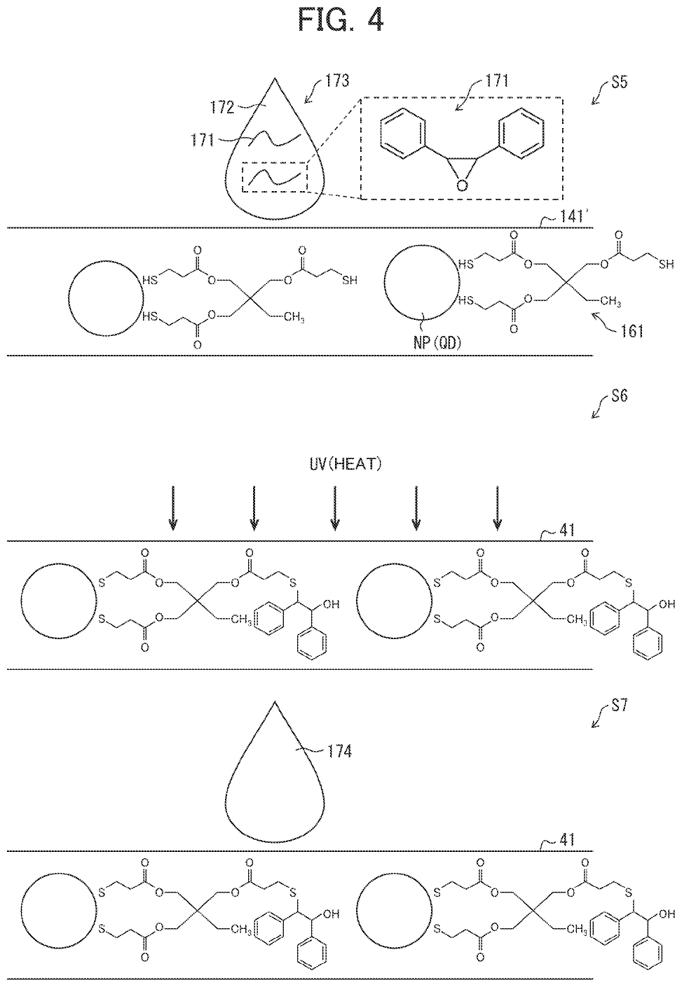

Moreover, as illustrated in FIG. 1 and FIG. 4 to be shown later, desirably, the ligand 42 has at least three thiol groups, and at least two of the at least three thiol groups are coordinated with a single nanoparticle NP. Note that, FIG. 1 exemplifies a case where the ligand 42 has four thiol groups, and two of the four thiol groups are coordinated to a single nanoparticle NP. FIG. 4 to be shown later exemplifies a case where the ligand 42 has three thiol groups, and two of the three thiol groups are coordinated to a single nanoparticle NP.

Thus, because a single ligand 42 is coordinated through a plurality of thiol groups with a single nanoparticle NP, the surface of the nanoparticle NP can be covered with the ligand 42 linked to the nanoparticle NP at a plurality of coordination sites. Such a feature can further enhance the chemical stability of the nanoparticle-containing film 41 against oxygen and water.

In this embodiment, as to the nanoparticle-containing film 41, a content ratio of the nanoparticles NP to the ligand 42 obtained by condensation of the first monomer and the second monomer (the nanoparticles NP:the ligand 42) is in a range of desirably 2:0.25 to 2:6 by weight ratio, and, more desirably, in a range of 2:1 to 2:4 by weight ratio. As to the ligand 42, most of the molecular skeleton is formed of an organic substance. Hence, the ligand 42 is mostly insulative. Hence, for example, from the viewpoint of carrier injection when the nanoparticle-containing film 41 is used for a light-emitting element, the nanoparticle-containing film 41 does not desirably contain an excess amount of the ligand 42. Hence, the content ratio is desirably within the above range.

A film thickness of the nanoparticle-containing film 41 may be appropriately set according to usage, and shall not be limited to a particular thickness. Note that a lower limit value of the film thickness of the nanoparticle-containing film 41 is an outermost particle size of one nanoparticle NP.

### Production Method for Nanoparticle-Containing Film

Described next will be a production method for the above nanoparticle-containing film 41.

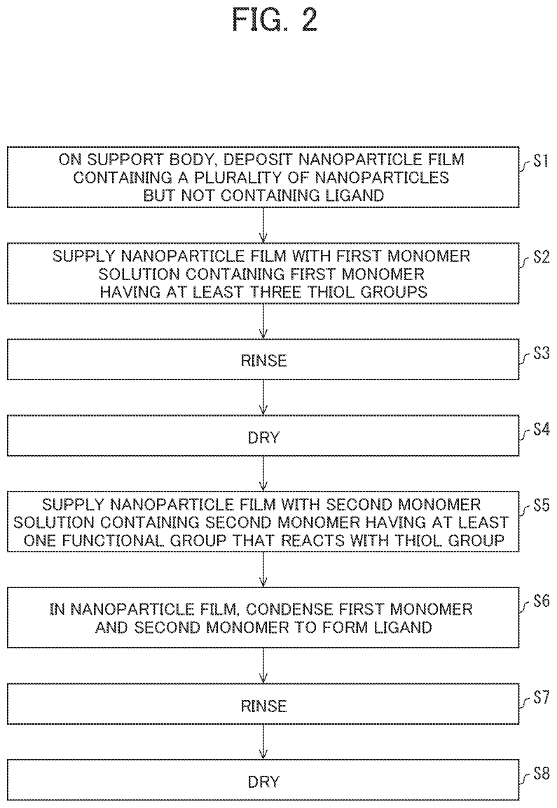

FIG. 2 is a flowchart showing an example of a production method for the nanoparticle-containing film 41 according to this embodiment.

As shown in FIG. 2, in order to form the nanoparticle-containing film 41, first, a nanoparticle-containing film (hereinafter referred to as a “nanoparticle film”) is deposited on a not-shown support body (Step S1: a nanoparticle film depositing step). The nanoparticle film contains a plurality of nanoparticles, but does not contain the ligand 42. Note that exemplified below is a case where the nanoparticle film, which contains the plurality of nanoparticles NP but does not contain the ligand 42, is a nanoparticle film formed of nanoparticles NP alone. That is, the nanoparticle film contains the plurality of nanoparticles NP, but does not contain a ligand. However, this embodiment shall not be limited to the above example. For example, if the nanoparticles NP are QDs, a commercially available QD colloidal solution typically contains a ligand. The ligand coordinated with the surface of the QDs can keep the QDs from agglomerating themselves. Hence, the nanoparticle film deposited at the nanoparticle film depositing step (Step S1) may contain a ligand (hereinafter referred to as an “original ligand”) other than the ligand 42 such as, for example, dodecanethiol, octanethiol, and oleic acid contained in a commercially available QD colloidal solution.

Next, the nanoparticle film is supplied with a first monomer solution containing the first monomer having at least three thiol groups. Hence, the nanoparticle film is supplied with the first monomer (Step S2: a first monomer supplying step). Next, excessive first monomer not coordinated with the nanoparticles NP is rinsed with a rinsing solvent for rinsing the first monomer (Step S3). Next, a solvent is removed from the nanoparticle film (i.e., a nanoparticle-containing film containing the nanoparticles NP, the first monomer, and a solvent used as the rinsing solvent) supplied with the first monomer, and the nanoparticle film is dried (Step S4). Next, the nanoparticle film is supplied with a second monomer solution containing the second monomer having at least one functional group reacting with a thiol group. Hence, the nanoparticle film is supplied with the second monomer (Step S5: a second monomer supplying step). Next, in the nanoparticle film (i.e., a nanoparticle-containing film containing the nanoparticles NP, the first monomer, the second monomer, and a solvent used for the second monomer solution) supplied with the second monomer, the first monomer and the second monomer are condensed to form the ligand 42 (Step S6: a ligand forming step). Hence, the nanoparticle-containing film 41 is formed to contain: the nanoparticles NP; the ligand 42; excessive second monomer not reacting with the first monomer; and a solvent used for the second monomer solution. Next, the excessive second monomer, which is contained in the nanoparticle-containing film 41 but does not react with the first monomer, is rinsed with a rinsing solvent for rinsing the second monomer (Step S7). After the rinse, the nanoparticle-containing film 41 contains: the nanoparticles NP; the ligand 42; and a solvent used as the rinsing solvent. Then, next, the solvent is removed from the nanoparticle-containing film 41, and the nanoparticle film is dried (Step S8). Hence, the nanoparticle-containing film 41 is formed to contain: the plurality of nanoparticles NP; and the ligand 42. Hereinafter, each of the above steps will be described in more detail.

At Step S1, a nanoparticle-dispersed liquid (a nanoparticle-containing colloidal solution), which contains the plurality of nanoparticles NP and a nanoparticle-dispersing solvent for dispersing the nanoparticles NP, is delivered in droplets and applied to the support body. After that, the solvent is removed, and the nanoparticle-dispersed liquid is dried. Hence, a nanoparticle film is deposited to contain the plurality of nanoparticles NP but not to contain the ligand.

The technique to apply the nanoparticle-dispersed liquid shall not be limited to a particular technique, and various known application techniques such as, for example, spin coating and inkjet printing may be used.

A concentration of the nanoparticles NP in the nanoparticle-dispersed liquid may be set in the same manner as conventionally set. The concentration shall not be limited to a particular concentration as long as the nanoparticles NP exhibit an applicable concentration or viscosity. For example, in using spin coating, a concentration of QDs is typically set to approximately 5 to 20 mg/mL, in order to obtain a practical QD film thickness. Note that the above example is merely an example, and the optimum concentration varies depending on a film depositing technique.

The solvent for dispersing nanoparticles (the nanoparticle-dispersing solvent) is not limited to a particular solvent as long as the solvent allows the nanoparticles NP to disperse therein if the nanoparticle-dispersed liquid does not contain a ligand. If the nanoparticle-dispersed liquid contains the original ligand as described above, the nanoparticle-dispersing solvent shall not be limited to a particular solvent as long as the solvent allows the nanoparticles NP and the original ligand to disperse therein while the nanoparticles NP are found alone, the original ligand is found alone, and the original ligand is coordinated with the nanoparticles NP.

If the nanoparticles NP are, for example, QDs, the nanoparticle-dispersing solvent is, for example, a nonpolar organic solvent. Whereas, if the nanoparticles NP are, for example, inorganic nanoparticles capable of transporting carriers, the nanoparticle-dispersing solvent is, for example, a polar organic solvent.

In order to dry and remove the solvent (the nanoparticle-dispersing solvent) contained in the nanoparticle-dispersed liquid applied to the support body, the solvent is, for example, baked. Note that a drying condition may be appropriately set, depending on, for example, a kind of the nanoparticle-dispersing solvent, so as to remove the nanoparticle-dispersing solvent. Hence, a drying temperature shall not be limited to a particular temperature. However, as described above, if the nanoparticles NP are either QDs or inorganic nanoparticles capable of transporting carriers, the drying temperature is within a range of desirably 60 to 120° C. Such a feature makes it possible to remove unnecessary solvent without causing thermal damage to the nanoparticles NP, so as to form the nanoparticle film. Note that a drying time may be set appropriately, depending on the drying temperature, so that the unnecessary solvent can be removed. Hence, the drying time shall not be limited to a particular time.

The first monomer solution used at Step S2 contains: the first monomer; and a first monomer dispersing solvent that allows the first monomer to disperse (dissolve). At Step S2, in supplying the first monomer solution, the first monomer solution is delivered in droplets and applied to the nanoparticle film. In the first monomer solution, the first monomer is dispersed (dissolved) in the first monomer dispersing solvent. When the first monomer solution is applied to the nanoparticle film, the first monomer can be coordinated with the nanoparticles NP.

Note that, as described above, the first monomer is a multi-thiol ligand. Hence, at Step S2, if the nanoparticle film contains the original ligand as described above, the first monomer solution may be supplied so that ligand exchange (ligand substitution) is performed.

The technique to apply the first monomer solution shall not be limited to a particular technique. Similar to the techniques to apply the nanoparticle-dispersed liquid, various known application techniques such as, for example, spin coating and inkjet printing may be used. Note that, as necessary, a holding time may be set to allow for penetration of the first monomer solution.

As to the first monomer solution to be used at the first monomer supplying step (Step S2), the first monomer has a concentration in a range of desirably 0.01 to 3 mol/L(M), and, more desirably, 0.1 to 0.3 mol/L.

The first monomer solution to be supplied (to be delivered in droplets) may be sufficient in amount as long as the first monomer solution is in contact with the entire nanoparticle film to which the ligand is added for ligand exchange. The first monomer solution may be delivered in excessive amount in droplets. As an example, 200 μL of the first monomer solution may be delivered in droplets to a nanoparticle film (e.g., a QD film) applied to the entire surface of a square substrate of 25 mm by 25 mm. Furthermore, for example, the first monomer solution may be stored in a container, and a multilayer stack including the support body and the nanoparticle film formed on the support body may be immersed in the first monomer. Here, as necessary, the first monomer solution in which the multilayer stack is immersed may be shaken.

Note that the amount of the first monomer to be supplied varies depending on, for example, a composition and a thickness of the nanoparticle film, a technique to supply the first monomer, and a size of an active region (e.g., a light-emitting region when the nanoparticle-containing film 41 is used as a light-emitting element). However, for one nanoparticle NP, the first monomer is supplied in sufficient amount regardless of the above conditions. Hence, the amount of the first monomer to be actually coordinated with the nanoparticles NP is likely to depend on the concentration of the first monomer contained in the first monomer solution. Then, at Step S3, the rinsing solvent for rinsing the first monomer removes the excessive first monomer not coordinated with the nanoparticles NP. For this reason, the concentration of the first monomer contained in the first monomer solution is desirably within the above range. The concentration of the first monomer contained in the first monomer solution is set within the above range. Thus, when the first monomer solution is supplied to the nanoparticle film, and permeates into the entire nanoparticle film, the nanoparticle-containing film 41 eventually formed can exhibit a content ratio of the nanoparticles NP to the ligand 42 in the desirable range described before.

The first monomer dispersing solvent to be used for the first monomer solution is a solvent in which the nanoparticle film is not dissolved but the first monomer can be dissolved. If the first monomer dispersing solvent is a solvent in which the nanoparticles NP in the nanoparticle film are dissolved, the nanoparticles NP with which the first monomer is not coordinated is dissolved. Inevitably, the nanoparticle film dissolves. Here, the solvent in which the nanoparticle film is not dissolved is a solvent in which the nanoparticles NP are not dissolved when the nanoparticle film formed at Step S1 does not contain a ligand. Furthermore, if the nanoparticle film formed at Step S1 contains the original ligand, neither the nanoparticles NP nor the original ligand is dissolved in the solvent while, in the solvent, the nanoparticles NP are found alone and the original ligand are coordinated with the nanoparticles NP.

If the nanoparticles NP are, for example, QDs, the first monomer dispersing solvent is, for example, a nonpolar organic solvent. Whereas, if the nanoparticles NP are, for example, inorganic nanoparticles capable of transporting carriers, the first monomer dispersing solvent is, for example, a nonpolar organic solvent.

Step S3 can be omitted. However, the nanoparticle film with the first monomer supplied (i.e., the nanoparticle-containing film containing the nanoparticles NP and the first monomer) contains the excessive first monomer as unnecessary first monomer not coordinated with the nanoparticles NP. Furthermore, if the nanoparticle film formed at Step S1 contains the original ligand (i.e., if the ligand exchange is performed at Step S2), the nanoparticle film with the first monomer supplied contains the excessive first monomer not coordinated with the nanoparticles NP, and additionally contains the unnecessary original ligand not coordinated with the nanoparticles NP.

Hence, at Step S3, the rinsing solvent (a rinsing liquid) is used to rinse the nanoparticle film, in order to successfully remove either the unnecessary first monomer contained in the nanoparticle film, or the unnecessary first monomer and original ligand contained in the nanoparticle film. Thanks to such a feature, the nanoparticle-containing film 41 can be formed not to eventually contain unnecessary ligand including the unnecessary ligand 42 not coordinated with the nanoparticles NP.

Note that the technique to rinse the nanoparticle film shall not be limited to a particular technique, and various rinsing techniques known in the art can be used. For example, the nanoparticle film obtained at Step S2 may be supplied with a sufficient amount of rinsing solvent as the rinsing solvent for rinsing the first monomer. The sufficient amount of rinsing solvent may be delivered in droplets to be applied.

Note that, as described above, the first monomer is a multi-thiol ligand. Thus, when the first monomer is coordinated with the nanoparticles NP, the nanoparticles NP with which the first monomer is coordinated become insoluble in any solvent. Hence, the rinsing solvent for rinsing the first monomer shall not be limited to a particular rinsing solvent as long as the rising solvent allows the excessive first monomer not coordinated with the nanoparticles NP to dissolve if the nanoparticle film formed at Step S1 does not contain any ligand (i.e., if the nanoparticle film supplied with the first monomer does not contain any ligand other than the first monomer). For this reason, as will be described later in a specific example, the rinsing solvent for rinsing the first monomer may be the same kind of solvent as, for example, the first monomer dispersing solvent.

Whereas, if the nanoparticle film formed at Step S1 contains the original ligand, (i.e., if the nanoparticle film supplied with the first monomer contains a ligand other than the first monomer), the rinsing solvent for rinsing the first monomer is a solvent for dissolving: the excessive ligand containing the excessive first monomer not coordinated with the nanoparticles NP; and a ligand (the original ligand), other than the first monomer, contained in the nanoparticle film.

At Step S4, the solvent is removed from the nanoparticle film and the nanoparticle film is dried. Hence, the obtained nanoparticle film (the nanoparticle-containing film) can contain the nanoparticles NP and the first monomer coordinated with the nanoparticles NP while the unnecessary first monomer is removed.

Similar to the drying at Step S1, the above drying involves, for example, baking. The drying condition is the same as that described at Step S1.

The second monomer solution used at Step S5 contains: the second monomer; and a second monomer dispersing solvent for dispersing (dissolving) the second monomer. At Step S5, in supplying the second monomer solution in which the second monomer is dispersed (dissolved) in the second monomer dispersing solvent, the second monomer solution is delivered in droplets and applied to the nanoparticle film suppled with the first monomer.

The technique to apply the second monomer solution shall not be limited to a particular technique. Similar to the techniques to apply the nanoparticle-dispersed liquid, various known application techniques such as, for example, spin coating and inkjet printing may be used. Note that, as necessary, a holding time may be set to allow for penetration of the second monomer solution.

The second monomer in the second monomer solution has a concentration in a range of desirably 0.01 to 3 mol/L(M), and, more desirably, 0.1 to 0.3 mol/L, because of the same reason as the concentration of the first monomer in the first monomer solution. Accordingly, the second monomer solution to be supplied (to be delivered in droplets) may be sufficient in amount as long as the second monomer solution is in contact with the entire nanoparticle film to which the second monomer is added because of the same reason as the amount of the first monomer solution to be supplied. Similar to the first monomer solution, the second monomer solution may also be delivered in excessive amount in droplets. As an example, 200 μL of the second monomer solution may be delivered in droplets to the nanoparticle film (for example, the QD film) formed on the entire surface of a square substrate of 25 mm by 25 mm. Furthermore, similar to the supply of the first monomer, for example, the second monomer solution may be stored in a container, and a multilayer stack including the support body and the nanoparticle film formed on the support body may be immersed in the second monomer. Hence, the second monomer may be supplied to the nanoparticle film. Here, as necessary, the second monomer solution in which the multilayer stack is immersed may be shaken.

The second monomer dispersing solvent to be used for the second monomer solution is a solvent in which the nanoparticle film is not dissolved but the second monomer can be dissolved. Here, the solvent in which the nanoparticle film is not dissolved is a solvent in which neither the nanoparticles NP nor the first monomer is dissolved when the first monomer is coordinated with the nanoparticles NP. However, as described above, the nanoparticles NP with which the first monomer is coordinated become insoluble in any solvent. For this reason, the second monomer dispersing solvent shall not be limited to a particular solvent as long as the solvent allows the second monomer to dissolve.

At Step S6, for example, the nanoparticle film, supplied with the first monomer and the second monomer, is irradiated with, for example, an ultraviolet ray (UV). Hence, the nanoparticle film is at least heat-treated or UV-treated, so that the first monomer and the second monomer are condensed. Thus, without using a catalyst, the nanoparticle film is at least simply heat-treated or UV-treated. Such a feature can cause a reaction of the first monomer and the second monomer in the nanoparticle film. As can be seen, when first monomer and the second monomer react together, the catalyst does not remain in the nanoparticle-containing film 41.

Note that the reaction conditions at the time of the reaction such as a reaction temperature, a reaction time, and a UV irradiation intensity may be set appropriately, so that the reaction of the first monomer and the second monomer is completed. The reaction conditions shall not be limited to particular conditions.

Thus, the only thiol groups to be capped with the second monomer are those not coordinated with the nanoparticles NP. Hence, the nanoparticle-containing film is formed to contain: the nanoparticles NP; the ligand 42; the excessive second monomer not reacting with the first monomer; and the solvent used for the second monomer solution.

Similar to Step S3, Step S7 can be omitted. However, as described above, the nanoparticle-containing film contains, as the unnecessary second monomer, the excessive second monomer not reacting with the first monomer.

Hence, at Step S7, the rinsing solvent (a rinsing liquid) is used to rinse the nanoparticle-containing film, in order to successfully remove the unnecessary second monomer contained in the nanoparticle-containing film. Thanks to such a feature, the nanoparticle-containing film 41 can be formed not to eventually contain unnecessary ligand including the excessive ligand 42 not coordinated with the nanoparticles NP.

Note that the technique to rinse the nanoparticle-containing film shall not be limited to a particular technique, and various rinsing techniques known in the art can be used as seen at Step S3. For example, the nanoparticle-containing film obtained at Step S6 may be supplied with a sufficient amount of rinsing solvent as the rinsing solvent for rinsing the second monomer. The sufficient amount of rinsing solvent may be delivered in droplets to be applied.

Note that, as described above, the nanoparticles NP with which the first monomer is coordinated is insoluble. When the second monomer bonds to the first monomer coordinated with the nanoparticles NP, such nanoparticles NP are insoluble in any solvent. Hence, the rinsing solvent for rinsing the second monomer shall not be limited to a particular solvent as long as the solvent dissolves the excessive second monomer not coordinated with the nanoparticles NP. For this reason, as will be described later in a specific example, the rinsing solvent for rinsing the second monomer may be the same kind of solvent as, for example, the second monomer dispersing solvent.

At Step S8, the solvent is removed from the nanoparticle-containing film and the nanoparticle-containing film is dried. Hence, the obtained nanoparticle-containing film 41 successfully contains the nanoparticles NP and the ligand 42 coordinated with the nanoparticles NP while the unnecessary second monomer is removed.

Similar to the drying at Step S1, the above drying involves, for example, baking. The drying condition is the same as that described at Step S1.

Note that, in this embodiment, the nonpolar organic solvent is desirably a solvent having a Hildebrand solubility parameter (8 value) of 9.3 or less, and more desirably, a solvent having the δ value of 7.3 or more and 9.3 or less. Furthermore, the nonpolar organic solvent is desirably a solvent having a relative permittivity (εᵣ value) of desirably 6.02 or less measured at approximately 20° C. to 25° C., and, more preferably, a solvent having the εᵣ value of 1.89 or more and 6.02 or less. If the nanoparticles NP are QDs, these nonpolar organic solvents neither degrade the QDs nor dissolve the QDs with which the ligand 42 is coordinated.

The nonpolar organic solvents shall not be limited to particular solvents. Examples of the nonpolar organic solvents include at least one solvent selected from the group consisting of toluene, hexane, octane, and chlorobenzene. Toluene, hexane, and octane are nonpolar organic solvents having the δ value of 7.3 or more and 9.3 or less, and the εᵣ value of 1.89 or more and 6.02 or less. These nonpolar organic solvents dissolve in particular QDs with which no ligand 42 is coordinated, and are easily available.

Whereas, the polar organic solvent is desirably a solvent having the δ value of, for example, 9.3 or more, and, more desirably, a solvent having the δ value of more than 9.3 and 12.3 or less. Furthermore, the δ value of the polar organic solvent is more desirably 10 or more. Hence, the polar organic solvent is still more desirably a solvent having the δ value of 10 or more and 12.3 or less. Moreover, the polar organic solvent is desirably a solvent having the εᵣ value of, for example, 6.02 or more, and, more desirably, a solvent having the εᵣ value of more than 6.02 and 46.7 or less.

The polar organic solvent shall not be limited to a particular solvent. Examples of the polar organic solvent include at least one solvent selected from the group consisting of propylene glycol monomethyl ether acetate (PGMEA), methanol, ethanol, acetonitrile, and ethylene glycol. At least one solvent selected from the group consisting of PGMEA, methanol, ethanol, acetonitrile, and ethylene glycol is a polar solvent having a solubility parameter of 10 or more. Such a solvent is easily available, but does not have many molecules. Hence, the first monomer can be uniformly dissolved.

### Example of how to Produce Nanoparticle-Containing Film

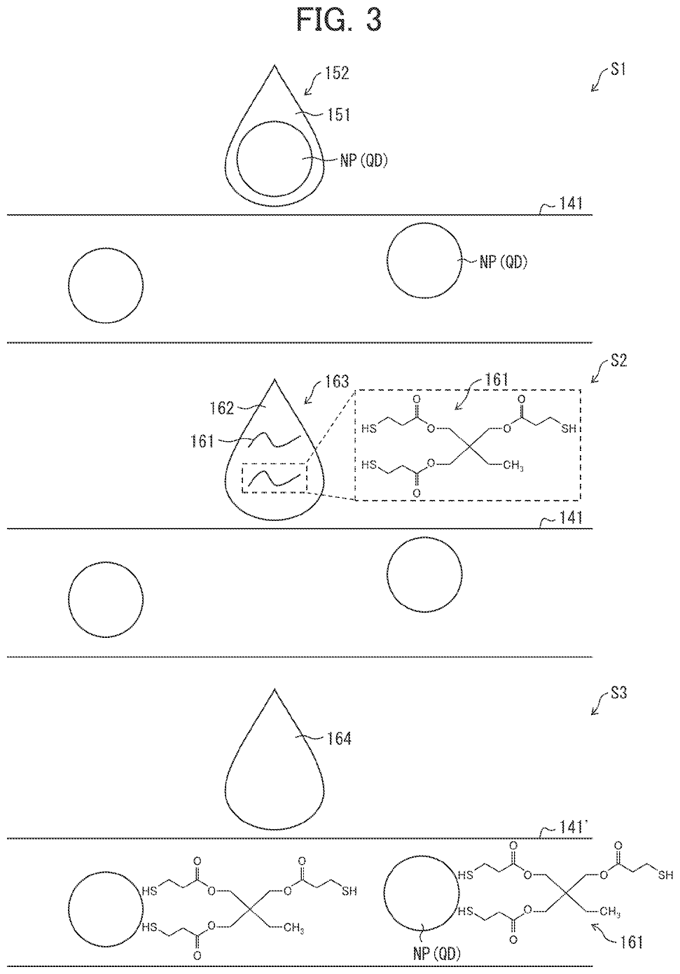

Specifically described below will be an exemplary production method for the nanoparticle-containing film 41 according to this embodiment, with reference to FIGS. 3 and 4.

FIG. 3 is a diagram schematically illustrating an example of some of the steps of producing the nanoparticle-containing film 41 according to this embodiment. Furthermore, FIG. 4 is a diagram schematically illustrating an example of other some of the steps of producing the nanoparticle-containing film 41 according to this embodiment. Note that FIG. 4 schematically illustrates some of the steps succeeding the steps of producing the nanoparticle-containing film 41 illustrated in FIG. 3. Moreover, in FIGS. 3, S1, S2, and S3 show Steps S1, S2, and S3 in FIG. 2. In addition, FIG. 4 illustrates some of the production steps succeeding the production steps illustrated in FIG. 3. In FIGS. 4, S5, S6, and S7 show Steps S5, S6, and S7 in FIG. 2.

Described below will be an exemplary case where the nanoparticles NP are QDs (quantum dots) each having a core/shell structure of InP/ZnS.

First, a not-shown support body is spin-coated with an InP/ZnS-octane dispersed liquid (a concentration of 20 mg/mL), serving as a nanoparticle-dispersed liquid 152, for 30 seconds at 2000 rpm. Note that the InP/ZnS-octane dispersed liquid is prepared in advance, with InP/ZnS dispersed in octane serving as a nanoparticle-dispersed solvent 151. Hence, the InP/ZnS-octane dispersed liquid has the above concentration.

Next, the InP/ZnS-octane dispersed liquid is baked at 80° C. for 15 minutes, and the octane is evaporated. Hence, as S1 in FIG. 3 illustrates, a QD film having a thickness of 30 nm is deposited to serve as a nanoparticle film 141. The nanoparticle film 141 contains a plurality of QDs serving as the nanoparticles NP, but does not contain any ligands.

Whereas, TMMP serving as a first monomer 161 is dispersed (dissolved) in ethanol serving as a first monomer dispersing solvent 162. Hence, as a first monomer solution 163, a TMMP-ethanol solution is prepared to have a concentration of 0.3 mol/L(M).

Next, as S2 in FIG. 3 illustrates, 200 μL of the first monomer solution 163 is delivered in droplets to the nanoparticle film 141 (a QD film). Then, in ten seconds after the first monomer solution 163 is delivered in droplets, the nanoparticle film 141 is spin-coated with the first monomer solution 163 for 30 seconds at 3000 rpm.

Furthermore, as S3 in FIG. 3 illustrates, immediately after the spin coating has started, 200 μL of ethanol is delivered in droplets three times (i.e., 600 μL in total) while the spin coating is performed, in order to serve as a rinsing solvent 164 for rinsing the first monomer. Thus, excessive first monomer 161 (TMMP) not coordinated with the QDs (the nanoparticles NP) is rinsed off and removed.

Operations from the delivery of the first monomer solution 163 in droplets to the rinsing off and removal of the excessive TMMP with ethanol are determined as one set, and the above operations are repeated two sets.

After that, the nanoparticle film 141′ is baked at 80° C. for 5 minutes, and the ethanol is vaporized. Hence, the nanoparticle film 141′ supplied with the first monomer 161 (TMMP) (i.e., a nanoparticle-containing film containing the nanoparticles NP (QDs) and the first monomer 161) is dried. Thus, the nanoparticle film 141′ is formed to include the nanoparticles NP and the first monomer 161 coordinated with the nanoparticles NP.

On the other hand, trans-stilbene oxide serving as a second monomer 171 is dispersed (dissolved) in toluene serving as a second monomer dispersing solvent 172. Hence, as a second monomer solution 173, a trans-stilbene oxide-toluene solution is prepared to have a concentration of 0.3 mol/L(M).

Next, as S5 in FIG. 4 illustrates, 200 μL of the second monomer solution 173 is delivered in droplets to the nanoparticle film 141′. Then, in ten seconds after the second monomer solution 173 is delivered in droplets, the nanoparticle film 141′ is spin-coated with the second monomer solution 173 for 30 seconds at 3000 rpm.

Next, the nanoparticle film 141′ supplied with the first monomer 161 (TMMP) and the second monomer 171 (trans-stilbene oxide) is irradiated with a UV ray at 120 mJ/cm² for 10 minutes. Thus, as S6 in FIG. 4 illustrates, the first monomer 161 (TMMP) and the second monomer 171 (trans-stilbene oxide) undergo a condensation reaction to form the ligand 42. Hence, the nanoparticle-containing film 41 is formed to contain the nanoparticles NP (QDs) and the ligand 42.

However, the nanoparticle-containing film 41 at this stage contains, other than the nanoparticles NP (QDs) and the ligand 42, excessive second monomer 171 not reacted with the first monomer 161 (TMMP).

Hence, as S7 in FIG. 4 illustrates, 200 μL of toluene serving as a rinsing solvent 174 for rinsing the second monomer is delivered in droplets to the nanoparticle-containing film 41. Then, in ten seconds after the toluene is delivered in droplets, the nanoparticle-containing film 41 is spin-coated with the rinsing solvent 174 for 30 seconds at 3000 rpm. Thus, the excessive second monomer 171 contained in the nanoparticle-containing film 41 is rinsed off and removed.

After that, the nanoparticle-containing film 41 is baked at 80° C. for 5 minutes, and the toluene is vaporized. Thus, the nanoparticle-containing film 41 is dried. Hence, the nanoparticle-containing film 41 is formed to contain the nanoparticles NP and the ligand 42 coordinated with the nanoparticles NP while the unnecessary second monomer 171 is removed.

As described above, in this embodiment, when the nanoparticle film 141 formed at Step S1 is supplied with the first monomer 161 at Step S2, the first monomer 161 is coordinated with the nanoparticles NP. After that, as described above, at Step S5, the nanoparticle film 141′, formed of the nanoparticle film 141 supplied with the first monomer 161, is supplied with the second monomer 171. At Step S6, the first monomer 161 and the second monomer 171 in the nanoparticle film 141′ are condensed, so that only the thiol groups contained in the first monomer 161 and not coordinated with the nanoparticles NP are capped with the second monomer 171. Thus, in this embodiment, the first monomer 161 and the second monomer 171 do not react with each other before coordinated with the nanoparticles NP, or the thiol groups are not capped at random (i.e., unnecessarily). Hence, the obtained nanoparticle-containing film 41 can have the ligand 42 coordinated in high density with the nanoparticles NP. Furthermore, the capping can improve chemical stability of the nanoparticle-containing film 41 against oxygen and water. Moreover, in this embodiment, the first monomer 161 and the second monomer 171 do not react with each other before coordinated with the nanoparticles NP. Such a feature keeps from forming unnecessary ligand chains. In addition, the first monomer 161 is coordinated with the nanoparticles NP, and after that, only the thiol groups contained in the first monomer 161 and not coordinated with the nanoparticles NP may be capped. Hence, compared with a case where the first monomer 161 and the second monomer 171 are condensed before being supplied to the nanoparticle film 141 obtained at Step S1, such a feature can reduce the amount of the second monomer 171 to be used for capping the thiol groups. Furthermore, the feature can also reduce the amount of the ligand 42. Hence, this embodiment can prevent an increase in resistance caused by an excessive amount of polymer and oligomer, and by a catalyst. Thus, this embodiment can provide a production method for the nanoparticle-containing film 41 having the ligand 42 coordinated in higher density with the nanoparticles NP than a conventional art, exhibiting high chemical stability against oxygen and water, and successfully reducing a drive voltage of a device when the nanoparticle-containing film 41 is incorporated into the device.

The nanoparticle-containing film 41 obtained in the above manner contains, as described above: the plurality of nanoparticles NP; and the ligand 42. As described above, the ligand 42 is a monomer containing: at least two thiol groups; and the spacer group 43 positioned between the at least two thiol groups, and the spacer group 43 contains: at least one linear chain that bonds the at least two thiol groups together; and at least one branched chain having a sulfide bond, and branched off from the at least one linear chain.

On the other hand, Patent Document 1 uses, as ligands, for example, a monomer having three or more thiol groups at a terminal of the monomer, and a monomer containing: two or more functional groups provided at a terminal of the monomer and capable of reacting with the thiol groups; and a spacer group between the two or more functional groups. These monomers react together to form either an oligomer or a polymer. With the oligomer or the polymer, the nanoparticles NP (QDs in Patent Document 1) are passivated.

The chemical formula (i) below is an exemplary reactant in Patent Document 1.

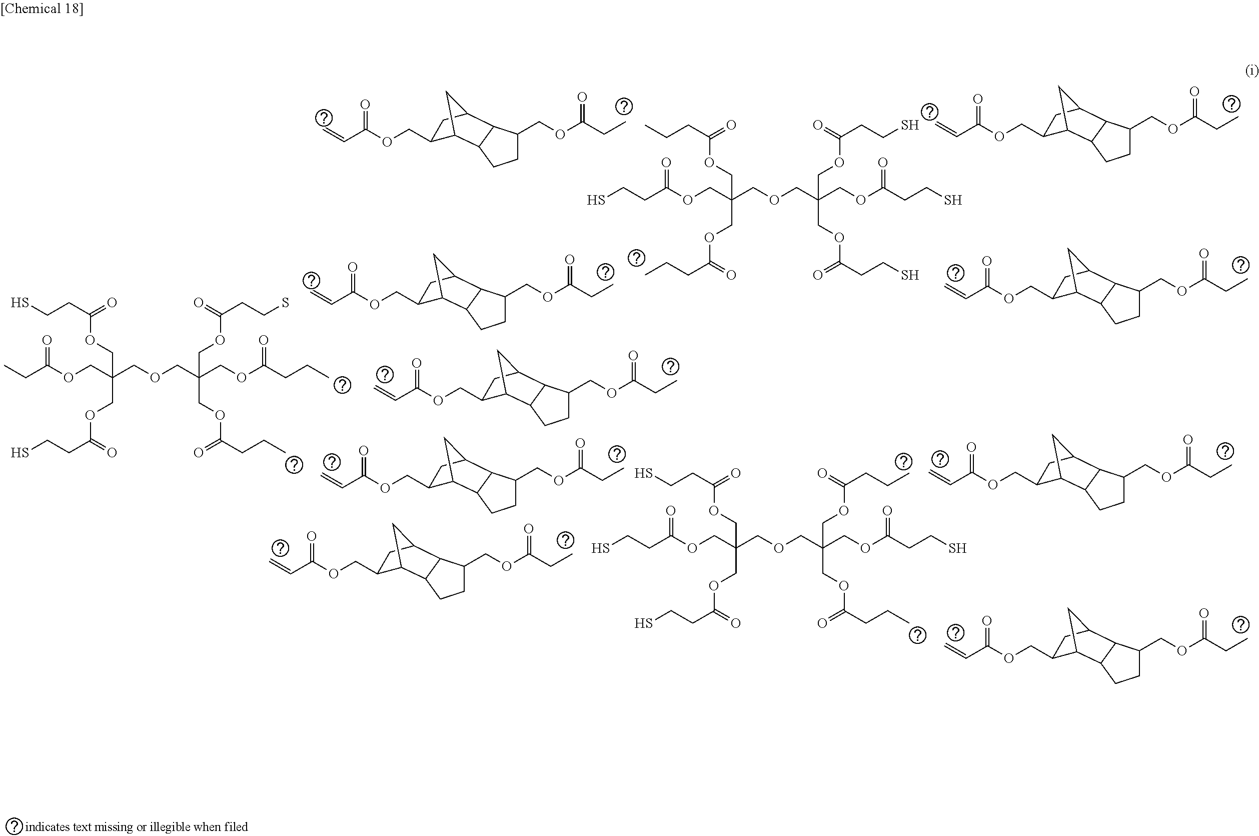

As described above, Patent Document 1 discloses a monomer having three or more thiol groups at a terminal of the monomer, and a monomer containing: two or more functional groups provided at a terminal of the monomer and capable of reacting with the thiol groups; and a spacer group between the two or more functional groups. These monomers react together in advance, and either the oligomer or the polymer is synthesized. Thus, as to the oligomer or the polymer of Patent Document 1, the chemical formula (i) shows that the thiol groups are easily capped at random (i.e., unnecessarily). Hence, as to the ligand to be used in Patent Document 1, the thiol groups capable of being coordinated with the nanoparticles NP are positioned at random, coordinated with little flexibility, and not controlled in volume. As a result, the ligand to be used in Patent Document 1 is coordinated in low density with the nanoparticles NP. Furthermore, if the nanoparticles NP are covered with a ligand that cannot be coordinated with the nanoparticles NP, a coordination site (a bonding hand) is unoccupied. Moreover, if the original ligand is coordinated with the nanoparticles NP, the original ligand might be left unexchanged, and remain. In addition, Patent Document 1 is utterly silent as to removal of the excess polymer or oligomer, and of the catalyst. Hence, the unnecessary polymer and oligomer, and the catalysts remain in the eventually obtained nanoparticle-containing film to increase the resistance. Hence, when the nanoparticle-containing film is incorporated into a device, the drive voltage of the device increases.

Whereas, in this embodiment, the above monomer is used to serve as the ligand 42. The monomer described above is a multidentate monomer containing at least two uncoordinated thiol groups as coordinating functional groups serving as coordinating hands for the nanoparticles NP, with some of the coordinating hands capped with a branched chain having a sulfide bond. Hence, the monomer is coordinated in higher density with the nanoparticles NP than a conventional monomer. Furthermore, the capping can improve chemical stability of the nanoparticle-containing film against oxygen and water. Thus, using the monomer as the ligand 42, this embodiment can provide the nanoparticle-containing film 41 with high resistance to atmospheric exposure. Furthermore, as described above, the nanoparticle-containing film 41 according to this embodiment does not contain an excessive amount of polymer or oligomer, or catalyst, for the nanoparticles NP. Hence, the nanoparticle-containing film 41 does not cause an increase in the drive voltage. Thanks to such features, the nanoparticle-containing film 41 according to this embodiment can have the ligand coordinated in higher density with the nanoparticles NP than a conventional film, exhibit high chemical stability against oxygen and water, and, when incorporated in a device, reduce an increase in drive voltage of the device further than a conventional film.

### Second Embodiment

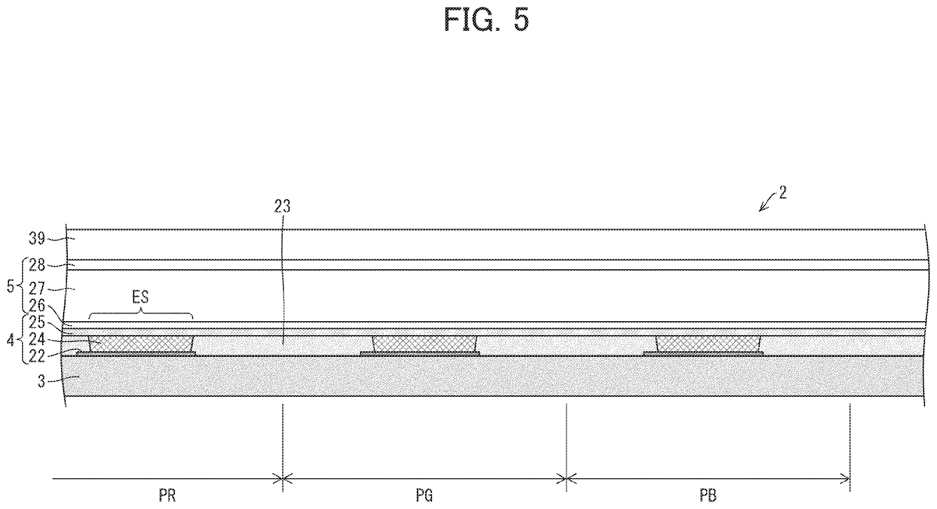

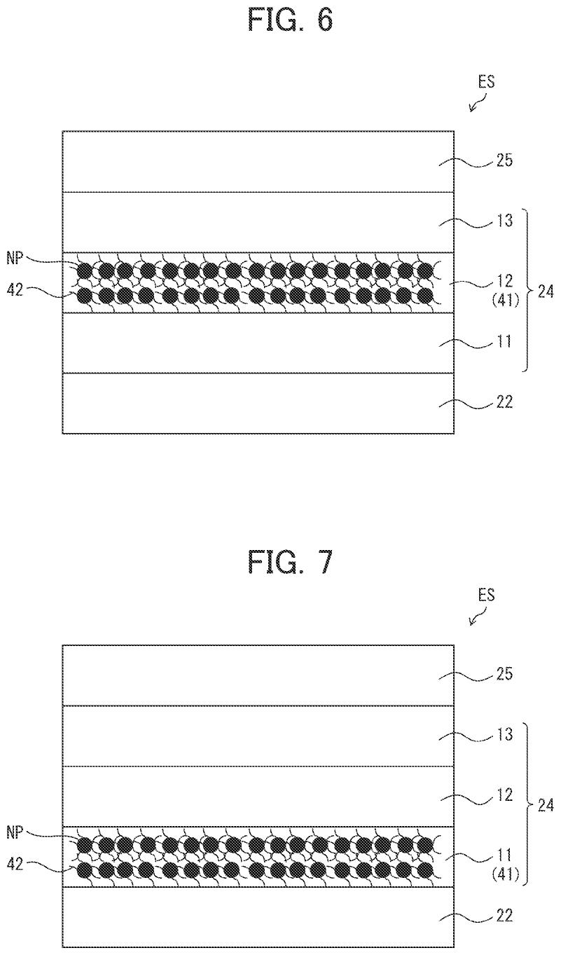

Another embodiment of the present disclosure will be described below, with reference to FIGS. 5 and 6. Note that, for convenience in description, like reference signs designate members having identical functions between this embodiment and the first embodiment. These members will not be elaborated upon repeatedly.

As described above, the nanoparticle-containing film 41 can be used suitably as a light-emitting layer of a light-emitting element for, for example, a display device. The light-emitting element may be used as, for example, a light source of a light-emitting device such as a display device or lighting device.

Described below will be an exemplary case where the nanoparticle-containing film 41 is a light-emitting layer of a light-emitting element for, for example, a display device.

### Schematic Configuration of Display Device

FIG. 5 is a cross-sectional view illustrating an exemplary schematic configuration of a main feature of a display device 2 according to a second embodiment.

The display device 2 has a plurality of pixels. Each of the pixels is provided with a light-emitting element ES. The display device 2 includes, as a substrate 3, an array substrate in which a drive element layer is formed. The display device 2 further includes: a plurality of the light-emitting elements ES having different emission wavelengths; a sealing layer 5; and a functional film 39, all of which are stacked on top of another above the substrate 3 in the stated order. Note that, in this embodiment, the direction from the light-emitting elements ES toward the substrate 3 of the display device 2 is referred to as a “downward direction”, and the direction from the substrate 3 toward the light-emitting elements ES of the display device 2 is referred to as an “upward direction”. Furthermore, in this embodiment, the term “below” means that a constituent feature is formed in a previous process before a comparative layer, and the term “above” means that a constituent feature is formed in a successive process after a comparative layer.

The display device 2 illustrated in FIG. 5 includes as pixels: a red pixel PR that emits a red light; a green pixel PG that emits a green light; and a blue pixel PB that emits a blue light. Between the pixels, a bank 23 is provided to serve as a pixel separating film to separate the neighboring pixels from one another. The bank 23 is insulative.

The display device 2 includes, as the plurality of light-emitting elements ES having different emission wavelengths: a red light-emitting element that emits a red light; a green light-emitting element that emits a green light; and a blue light-emitting element that emits a blue light. The red pixel PR is provided with the red light-emitting element serving as a light-emitting element ES. The green pixel PG is provided with the green light-emitting element serving as a light-emitting element ES. The blue pixel PB is provided with the blue light-emitting element serving as a light-emitting element ES.

The light-emitting element layer 4 includes the plurality of light-emitting elements ES provided for the respective pixels. Above the substrate 3, the layers of each of the light-emitting elements ES are stacked on top of another.

The substrate 3 functions as a support body for forming the layers of each light-emitting element ES. The substrate 3 is an array substrate, and provided with, for example, a TFT (thin-film transistor) layer to serve as a drive element layer. The TFT layer is provided with a drive circuit including such a drive element as a TFT. The drive circuit functions as a pixel circuit, and drives a light-emitting element ES.

The light-emitting element layer 4 includes, as an example: a plurality of cathodes 22 (first electrodes, lower electrodes); an anode 25 (a second electrode, an upper electrode); a functional layer 24 provided between each cathode 22 and the anode 25, and containing at least a light-emitting layer, and the bank 23 insulative and covering an edge of each of the lower electrodes (the cathodes 22 in the example illustrated in FIG. 5) provided on the substrate 3.

Note that, in this embodiment, the layers between the cathode 22 and the anode 25 are collectively referred to as the functional layer 24 (also referred to as an active layer). Furthermore, hereinafter, the light-emitting layer is referred to as an “EML”. The functional layer 24 may be either a single layer including the EML alone, or a multilayer including a functional layer other than the EML. Examples of the functional layer other than the EML include an electron transport layer and a hole transport layer. Hereinafter, the electron transport layer is referred to as an “ETL”, and the hole transport layer is referred to as an “HTL”.

This embodiment exemplifies a case where, as described above, each lower electrode is the cathode 22 (a patterned cathode), the upper electrode is the anode 25 (a common anode), and the cathode 22, the bank 23, the functional layer 24, and the anode 25 are stacked on top of another in the stated order above the substrate 3.

However, this embodiment shall not be limited to such an example. The lower electrode may be the anode 25 (a patterned anode), the upper may be the cathode 22 (a common cathode), and the anode 25, the bank 23, the functional layer 24, and the cathode 22 may be stacked in the stated order above the substrate 3.

The bank 23 is used as an edge cover to cover the edge of the patterned lower electrode, and also functions as a pixel separating film. As an example, the lower electrodes and the functional layers 24 are separated (patterned) for the respective pixels with the bank 23. Hence, in the light-emitting element layer 4, each of the light-emitting elements ES is provided for a corresponding one of the pixels. The lower electrode of each light-emitting element ES is electrically connected to a TFT of the substrate 3. Whereas, the upper electrode is provided as a common electrode in common to all the pixels. Note that the configuration of the light-emitting element ES will be described later in detail.

The light-emitting element layer 4 is covered with the sealing layer 5. The sealing layer 5 is transparent to light, and includes, for example, a first inorganic sealing film 26, an organic sealing film 27, and a second inorganic sealing film 28 in the stated order from below (i.e., from toward the light-emitting element layer 4). Note that the configuration of the sealing layer 5 shall not be limited to such a configuration. The sealing layer 5 may be formed of an inorganic sealing film alone, or a multilayer stack including five layers or more such as an organic sealing film and an inorganic sealing film. Furthermore, the sealing layer 5 may be, for example, a sealing glass. The sealing layer 5 seals the light-emitting elements ES, thereby making it possible to prevent water and oxygen from penetrating into the light-emitting elements ES.

Each of the first inorganic sealing film 26 and the second inorganic sealing film 28 can be formed of a silicon oxide film, a silicon nitride film, a silicon oxynitride film, or a multilayer film including these films. These films can be formed by, for example, chemical vapor deposition (CVD). The organic sealing film 27 is a light-transparent organic film thicker than the first inorganic sealing film 26 and the second inorganic sealing film 28. The organic sealing film 27 can be formed of an applicable photosensitive resin such as polyimide resin and acrylic resin.

Note that, as illustrated in FIG. 5, the display device 2 may include the functional film 39 provided on the sealing layer 5 and having at least one of, for example, an optical compensation function, a touch sensor function, and a protection function.

### Schematic Configuration of Light-Emitting Element

FIG. 6 is a schematic view of an example of a light-emitting element ES according to this embodiment.

As illustrated in FIG. 6, the light-emitting element ES includes, for example: the cathode 22; the ETL11; the EML12; the HTL13; and the anode 25, all of which are stacked on top of another in the stated order from below. The light-emitting element ES is an electroluminescent element that emits light when a voltage is applied to the EML12.

Note that, in the display device 2, the substrate 3 functions as a support body for forming the layers of the light-emitting element ES. Hence, the layers of the light-emitting element ES are formed above the substrate serving as the support body. Thus, when the light-emitting element ES is produced as an individual product, the light-emitting element ES may also be referred to as a light-emitting element including the substrate as a support body.

The cathode 22 and the anode 25 are connected to a not-shown power source (e.g., a DC power source), so that a voltage is applied between the cathode 22 and the anode 25.

The cathode 22 is an electrode that receives a voltage and supplies the electrons to the EML 12. The anode 25 is an electrode that receives a voltage and supplies the holes to the EML 12.

At least one of the cathode 22 or the anode 25 is made of a light-transparent material. Note that either the cathode 22 or the anode 25 may be formed of a light-reflective material. The light-emitting element ES can release light from toward an electrode made of a light-transparent material.

For example, if the light-emitting element ES is a bottom-emission light-emitting element, the upper electrode is a light-reflective electrode, and the lower electrode is a light-transparent electrode. Whereas, if the light-emitting element ES is a top-emission light-emitting element, the upper electrode is a light-transparent electrode, and the lower electrode is a light-reflective electrode. Note that the light-reflective electrode may be a multilayer stack including a layer made of a light-transparent material and a layer made of a light-reflective material.

Materials of the cathode 22 and the anode 25 shall not be limited to particular materials. These materials can be the same materials as conventional materials to be used for anodes and cathodes of light-emitting elements.

The cathode 22 is made of, for example, a material having a relatively small work function. Examples of the material include: aluminum; silver (Ag); Ba; ytterbium (Yb); calcium (Ca); a lithium (Li)-A1 alloy; a Mg-A1 alloy; a Mg—Ag alloy; a Mg-indium (In) alloy; and an A1-aluminum oxide (Al₂O₃) alloy.

The anode 25 is made of, for example, a material having a relatively large work function. Examples of the material include: tin-doped indium oxide (ITO); zinc-doped indium oxide (IZO); aluminum-doped zinc oxide (AZO); gallium-doped zinc oxide (GZO); and antimony-doped tin oxide (ATO). These materials may be used alone or in combination of two or more as appropriate.

The ETL 11 (a first carrier transport layer) is a layer to transport the electrons, supplied from the cathode 22, to the EML 12. The ETL 11 is made of an electron transporting material. The electron transporting material may be either an organic material or an inorganic material.

If the electron transporting material is an organic material, examples of the organic material include such conductive polymer materials as: 1,3,5-tris(1-phenyl-1H-benzimidazole-2-yl)benzene (TPBi); 3-(biphenyl-4-yl)-5-(4-tert-butylphenyl)-4-phenyl-4H-1,2,4-triazole (TAZ); bathophenanthroline (Bphen); and tris (2,4,6-trimethyl-3-(pyridin-3-yl) phenyl)borane (3 TPYMB). Furthermore, if the electron transporting material is an inorganic material, examples of the inorganic material include such n-type semiconductor materials as: a metal oxide; a group II-VI compound semiconductor; a group III-V compound semiconductor; a group IV-IV compound semiconductor; and an amorphous semiconductor. Examples of these n-type semiconductor materials include the exemplary n-type semiconductor materials described before. Among these materials, the metal oxide is excellent in durability and high in reliability, and is easily applicable to form a film. These electron transporting materials may be used alone, or in combination of two or more as appropriate.

The HTL 13 (a second carrier transport layer) is a layer to transport the holes, supplied from the anode 25, to the EML 12. The HTL 13 is made of a hole transporting material. The hole transporting material may also be either an organic material or an inorganic material.

If the hole transporting material is an organic material, examples of the organic material include conductive polymer materials such as: poly(3,4-ethylenedioxythiophene)-poly(styrenesulfonic acid) (PEDOT-PSS), poly[(9,9-dioctylfluorenyl-2,7-diyl)-co-(4,4′-(N-(4-sec-butylphenyl)diphenylamine))] (TFB), and poly(N-vinylcarbazole) (PVK). Furthermore, if the hole transporting material is an inorganic material, examples of the inorganic material include p-type semiconductor materials such as: metal oxide; a group II-VI compound semiconductor; a group III-V compound semiconductor; a group IV-IV compound semiconductor; an amorphous semiconductor; and a thiocyanate compound. Examples of these p-type semiconductor materials include the exemplary p-type semiconductor materials described before. These hole transporting materials may be used alone, or in combination of two or more as appropriate.

The EML12 contains a light-emitting material, and emits light by recombination of the electrons transported from the cathode 22 and the holes transported from the anode 25.

The light-emitting element ES according to this embodiment is a QLED, and the EML 12 contains nano-sized QDs used as a light-emitting material and corresponding to a color of light to be emitted. Note that the QDs shall not be particularly limited QDs, and may be, for example, the QDs exemplified in the first embodiment.

In the light-emitting element ES, the holes and the electrons recombine together in the EML 12 by a drive current between the anode 25 and the cathode 22, which forms an exciton. While the exciton transforms from a conduction band level to a valence band level of a QD, light is released.

As described above, the EML12 of the light-emitting element ES is a nanoparticle-containing film containing QDs as the nanoparticles NP. The light-emitting element ES according to this embodiment includes, as the EML12, the nanoparticle-containing film 41 described in the first embodiment. Thus, the EML 12 contains the above described QDs as the nanoparticles NP, and also contains the ligand 42 as a ligand.

The EML 12 contains the ligand 42 as a ligand. That is why the ligand is coordinated in higher density with the QDs than the conventional art, and the chemical stability against oxygen and water is higher than the conventional art. Furthermore, the drive voltage of the light-emitting element ES can be reduced lower than the conventional art. Hence, this embodiment can provide the light-emitting element ES, and the display device 2, including the EML 12. The EML 12 has a ligand coordinated in higher density with QDs, and exhibits higher chemical stability against oxygen and water, than the conventional art, thereby successfully reducing the drive voltage.

### Production Method for Light-Emitting Element

The light-emitting element ES illustrated in FIG. 6 can be produced by a method below. First, the cathode 22 is formed on the substrate 3 (an anode forming step). Next, the ETL 11 is formed on the cathode 22 (an ETL forming step). Next, the EML 12 is formed on the ETL 11 (an EML forming step). Next, the HTL 13 is formed on the EML 12 (an HTL forming step). Next, the anode 25 is formed on the HTL 13 (an anode forming step). Note that, after the anode formation step, the multilayer stack (the cathode 22 to anode 25) formed on the substrate 3 may be sealed with a sealing member.

The cathode 22 and the anode 25 are formed by, for example, physical vapor deposition (PVD) including sputtering and vacuum evaporation, spin coating, or inkjet printing.

If the ETL 11 or the HTL 13 is made of an organic material, the ETL 11 or the HTL 13 is formed ideally by, for example, vacuum evaporation, spin coating, or inkjet printing. If the ETL 11 or the HTL 13 is made of an inorganic material, the ETL 11 or the HTL 13 is formed ideally by, for example, PVD such as sputtering and vacuum evaporation, spin coating, or inkjet printing.

The EML 12 is formed by the method described in the first embodiment with reference to FIGS. 2 to 4. Here, used as the nanoparticles NP are nano-sized QDs depending on colors of light to be emitted. The QDs shall not be limited to particular QDs, and may be, for example, various kinds of the exemplified QDs. However, as described before, recent years have seen impacts of environmental issue and the resulting development of QLEDs using Cd-free quantum dots that do not substantially contain Cd. These quantum dots suffer low resistance to air exposure in particular, and properties of such quantum dots produced by a conventional art are significantly degraded by oxygen and water in the atmosphere. However, the EML 12 is formed by the method described in the first embodiment. Hence, even if the above QDs are used as QDs, the ligand can be coordinated in higher density with the QDs than the conventional art. As a result, the obtained light-emitting element ES can operate on a lower drive voltage, and exhibit higher chemical stability against oxygen and water, than a conventional light-emitting element.

Note that, in this embodiment, a thickness of each of the layers included in the light-emitting element ES shall not be limited to a particular thickness, and may be set the same as a conventional thickness.

### Third Embodiment

Still another embodiment of the present disclosure will be described below, with reference to FIG. 7. Note that, for convenience in description, like reference signs designate members having identical functions between this embodiment and the first and embodiments. These members will not be elaborated upon repeatedly.

As described in the first embodiment, the nanoparticles NP according to the present disclosure may be inorganic nanoparticles capable of transporting carriers. Described in this embodiment will be an exemplary case where the nanoparticles NP are inorganic nanoparticles capable of transporting carriers, and where the nanoparticle-containing film 41 is, for example, a carrier transport layer of the light-emitting element ES included in the display device 2.

### Schematic Configuration of Light-Emitting Element

FIG. 7 is a schematic view of an example of a light-emitting element ES according to this embodiment.

The light-emitting element ES illustrated in FIG. 7 includes the nanoparticle-containing film 41 described in the first embodiment and serving as the ETL 11. As to the light-emitting element ES illustrated in FIG. 7, the ETL 11 contains inorganic nanoparticles serving as the nanoparticles NP and capable of transporting the electrons. In addition, the ETL 11, not the EML 12, contains the ligand 42. The EML 12 may contain the ligand 42 as a ligand, as seen in the second embodiment. The EML 12 may contain a ligand other than the ligand 42. If a ligand other than the ligand 42 is used for the EML 12, the ligand used for the EML 12 shall not be limited to a particular ligand, and various known ligands can be used. Furthermore, in this embodiment, the EML12 shall not be limited to a QD light-emitting layer. The light-emitting element ES may be a QLED. Alternatively, the light-emitting element ES may be either an organic light-emitting diode (OLED), or an inorganic light-emitting diode (IOLED). Note that if the light-emitting element ES is either an OLED or an IOLED, the EML 12 is formed of, for example, either an organic light-emitting material or an inorganic light-emitting material, such as a low-molecular fluorescent (or phosphorescent) dye or a metal complex. Otherwise, the light-emitting element ES according to this embodiment is the same as the light-emitting element ES according to the second embodiment.

As can be seen, if the light-emitting element ES is either an OLED or an IOLED, the holes and the electrons recombine together in the EML 12 by a drive current between the cathode 22 and the anode 25, which forms an exciton. While the exciton transforms to the ground state, light is released.

Note that, in this embodiment, the inorganic nanoparticles capable of transporting the electrons and used for the ETL11 shall not be limited to particular inorganic nanoparticles as long as the inorganic nanoparticles are capable of transporting the electrons. Examples of the inorganic nanoparticles capable of transporting the electrons include the electron-transporting inorganic nanoparticles exemplified in the first embodiment 1.

### Production Method for Light-Emitting Element

The light-emitting element ES illustrated in FIG. 7 can be produced by the method described in the second embodiment except that the ETL 11 is deposited by the method described in the first embodiment with reference to FIGS. 2 to 4.

Note that if the light-emitting element ES is a QLED and a ligand other than the ligand 42 is used for the EML 12, the EML 12 may be formed of a support body (an underlayer; that is, the ETL 11 in this embodiment) coated with a QD dispersed liquid containing QDs and a ligand, as can be seen in a conventional method. In this case, for example, ligand exchange and rinsing are performed as necessary, and, after that, the solvent is removed.

Furthermore, if the light-emitting element ES is an OLED or an IOLED, the EML12 can be formed by, for example, coating with separate light-emitting materials, using a fine metal mask (FMM), and evaporating the light-emitting materials, or by inkjet printing with a light-emitting material.

In this embodiment, the ETL11 contains the ligand 42 as a ligand. That is why the ligand is coordinated in higher density with the inorganic nanoparticles than the conventional art, and the chemical stability against oxygen and water is higher than the conventional art. Furthermore, the drive voltage of the light-emitting element ES can be reduced lower than the conventional art. Hence, this embodiment can provide the light-emitting element ES, and the display device 2, including the ETL 11. The ETL 11 has a ligand coordinated in higher density with the inorganic nanoparticles, and exhibits higher chemical stability against oxygen and water, than the conventional art, thereby successfully reducing the drive voltage.

### Modifications

Note that, similar to FIG. 6, FIG. 7 illustrates an exemplary case where the cathode 22, the ETL11, the EML12, the HTL13, and the anode 25 are stacked on top of another in the stated order from below. However, this embodiment shall not be limited to the above example. In this embodiment, as described in the second embodiment, the lower electrode may be the anode 25 (a patterned anode), the upper may be the cathode 22 (a common cathode), and the anode 25, the bank 23, the functional layer 24, and the cathode 22 may be stacked on top of another in the stated order above the substrate 3.

Furthermore, this embodiment exemplifies a case where the nanoparticles NP are inorganic nanoparticles capable of transporting the electrons, and where the nanoparticle-containing film 41 is the ETL 11 of the light-emitting element ES. However, this embodiment shall not be limited to the above example. The nanoparticles NP may be inorganic nanoparticles capable of transporting the holes, and the nanoparticle-containing film 41 may be the HTL 13 of the light-emitting element ES.

In this case, the inorganic nanoparticles used for the HTL 13 and capable of transporting the holes shall not be limited to particular inorganic nanoparticles as long as the inorganic nanoparticles are capable of transporting the holes. Examples of the inorganic nanoparticles capable of transporting the holes include the hole-transporting inorganic nanoparticles exemplified in the first embodiment 1. In this case, the HTL 13 is formed by the method described in the first embodiment with reference to FIGS. 2 to 4.

Furthermore, as described before, the nanoparticles NP such as QDs are used not only for light-emitting elements. The nanoparticles NP are used in various fields such as light-emitting elements, solar cells, and wavelength conversion members. The nanoparticle-containing film 41 may be, for example, a QD-containing film for a solar cell, or a wavelength converting layer for a wavelength conversion member.

The present disclosure shall not be limited to the embodiments described above, and can be modified in various manners within the scope of claims. The technical aspects disclosed in different embodiments are to be appropriately combined together to implement another embodiment. Such an embodiment shall be included within the technical scope of the present disclosure. Moreover, the technical aspects disclosed in each embodiment may be combined together to achieve a new technical feature.

### REFERENCE SIGNS LIST

11 ETL (Carrier Transport Layer)
12 EML (Light-Emitting Layer)
13 HTL (Carrier Transport Layer)
22 Cathode
25 Anode
41 Nanoparticle-Containing Film
42 Ligand
43 Spacer Group
141, 141′ Nanoparticle Film
161 First Monomer
162 First Monomer Dispersing Solvent (Solvent)
163 First Monomer Solution
171 Second Monomer
NP Nanoparticles
ES Light-Emitting Element

1. A Nanoparticle-containing film, comprising:
a plurality of nanoparticles; and a ligand,
wherein the ligand is a monomer containing: at least two thiol groups; and a spacer group positioned between the at least two thiol groups, and
the spacer group contains: at least one liner chain that bonds the at least two thiol groups together; and at least one branched chain having a sulfide bond, and branched off from the at least one liner chain.

2. The nanoparticle-containing film according to claim 1,
wherein the ligand is a monomer obtained by condensation of at least one first monomer and at least one second monomer,
the at least one first monomer is a monomer having at least three thiol groups, and
the at least one second monomer is a monomer having one functional group that reacts with a thiol group.

3. The nanoparticle-containing film according to claim 2,
wherein the at least one first monomer is a monomer having at least four thiol groups, and
the ligand is a monomer obtained by condensation of: one of the at least one first monomer; and at least two of the at least one second monomer.

4. The nanoparticle-containing film according to claim 2,
wherein the at least one first monomer is a monomer represented by a general formula (1) below 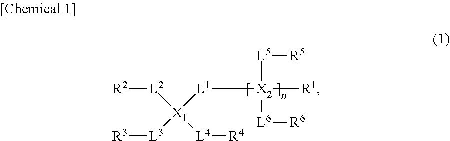
and
wherein, in the general formula (1), X¹ and X² each independently represent a carbon atom, a substituted or an unsubstituted arylene group having 6 to 30 carbon atoms, a substituted or an unsubstituted heteroarylene group having 6 to 30 carbon atoms, a substituted or an unsubstituted cycloalkylene group having 3 to 30 carbon atoms, or a substituted or an unsubstituted heterocycloalkyl group having 3 to 30 carbon atoms, L¹ to L⁶ each independently represent either an alkylene group having 1 to 30 carbon atoms, or an alkenylene group having 2 to 30 carbon atoms, in which a single bond, a substituted, or an unsubstituted alkylene group having 1 to 30 carbon atoms, a substituted or an unsubstituted alkenylene group having 2 to 30 carbon atoms, or at least one methylene group that is not adjacent to each other is substituted with a substituent selected from a sulfonyl group, a carbonyl group, an ether group, a sulfide group, a sulfoxide group, an ester group, a —C(═O) NRa— group, a —NRb— group, and a combination thereof, Ra and Rb each independently represent a hydrogen atom or an alkyl group having 1 to 30 carbon atoms, R¹ to R⁶ each independently represent a hydrogen atom, a thiol group, a substituted or an unsubstituted alkyl group having 1 to 30 carbon atoms, a substituted or an unsubstituted aryl group having 6 to 30 carbon atoms, a substituted or an unsubstituted heteroaryl group having 3 to 30 carbon atoms, a substituted or an unsubstituted cycloalkyl group having 3 to 30 carbon atoms, a substituted or an unsubstituted heterocycloalkyl group having 3 to 30 carbon atoms, a substituted or an unsubstituted alkenyl group having 2 to 30 carbon atoms, or a substituted or an unsubstituted alkynyl group having 2 to 30 carbon atoms, n represents an integer of 0 to 2, if n is 0, at least three of R¹ to R⁴ are thiol groups, and if n is 1 or 2, at least three of R¹ to R⁶ are thiol groups.

5. The nanoparticle-containing film according to claim 2,
wherein the at least one second monomer is one monomer selected from the group consisting of: an epoxy-based compound; an oxazoline-based compound; and a nitrile-based compound.

6. The nanoparticle-containing film according to claim 2,
wherein the at least one second monomer is a monomer having a π-conjugated compound further having a π-conjugated functional group.

7. The nanoparticle-containing film according to claim 1,
wherein a single ligand included in the ligand is coordinated with at least two of the plurality of nanoparticles.

8. The nanoparticle-containing film according to claim 1,
wherein the ligand has at least three thiol groups, and
at least two of the at least three thiol groups are coordinated with a single nanoparticle included in the plurality of nanoparticles.

9. The nanoparticle-containing film according to claim 1,
wherein the ligand is a monomer represented by a general formula (2) below 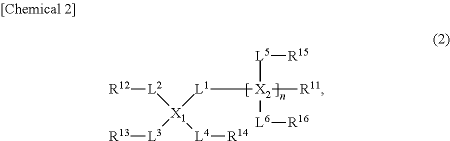
and
wherein, in the general formula (2), X¹ and X² each independently represent a carbon atom, a substituted or an unsubstituted arylene group having 6 to 30 carbon atoms, a substituted or an unsubstituted heteroarylene group having 6 to 30 carbon atoms, a substituted or an unsubstituted cycloalkylene group having 3 to 30 carbon atoms, or a substituted or an unsubstituted heterocycloalkyl group having 3 to 30 carbon atoms, L¹ to L⁶ each independently represent either an alkylene group having 1 to 30 carbon atoms, or an alkenylene group having 2 to 30 carbon atoms, in which a single bond, a substituted, or an unsubstituted alkylene group having 1 to 30 carbon atoms, a substituted or an unsubstituted alkenylene group having 2 to 30 carbon atoms, or at least one methylene group that is not adjacent to each other is substituted with a substituent selected from a sulfonyl group, a carbonyl group, an ether group, a sulfide group, a sulfoxide group, an ester group, a —C(═O) NRa— group, a —NRb— group, and a combination thereof, Ra and Rb each independently represent a hydrogen atom or an alkyl group having 1 to 30 carbon atoms, R¹¹ to R¹⁶ each independently represent a hydrogen atom, a thiol group, a substituted or an unsubstituted alkyl group having 1 to 30 carbon atoms, a substituted or an unsubstituted aryl group having 6 to 30 carbon atoms, a substituted or an unsubstituted heteroaryl group having 3 to 30 carbon atoms, a substituted or an unsubstituted cycloalkyl group having 3 to 30 carbon atoms, a substituted or an unsubstituted heterocycloalkyl group having 3 to 30 carbon atoms, a substituted or unsubstituted alkenyl group having 2 to 30 carbon atoms, a substituted or unsubstituted alkynyl group having 2 to 30 carbon atoms, a substituted or an unsubstituted alkyl group bonded through a sulfide bond and having 1 to 30 carbon atoms, a substituted or an unsubstituted aryl group bonded through a sulfide bond and having 6 to 30 carbon atoms, a substituted or an unsubstituted heteroaryl group bonded through a sulfide bond and having 3 to 30 carbon atoms, a substituted or unsubstituted cycloalkyl group bonded through a sulfide bond and having 3 to 30 carbon atoms, a substituted or an unsubstituted hererocycloalkyl group bonded through a sulfide bond and having 3 to 30 carbon atoms, a substituted or an unsubstituted alkenyl group bonded through a sulfide bond and having 2 to 30 carbon atoms, or a substituted or an unsubstituted alkynyl group bonded through a sulfide bond and having 2 to 30 carbon atoms, n represents an integer of 0 to 2, if n is 0, at least three of R¹¹ to R¹⁴ are thiol groups, and at least one of R¹¹ to R¹⁴ is a substituted or an unsubstituted alkyl group bonded through a sulfide bond and having 1 to 30 carbon atoms, a substituted or unsubstituted aryl group bonded through a sulfide bond and having 6 to 30 carbon atoms, a substituted or an unsubstituted heteroaryl group bonded through a sulfide bond and having 3 to 30 carbon atoms, a substituted or an unsubstituted cycloalkyl group bonded through a sulfide bond and having 3 to 30 carbon atoms, a substituted or an unsubstituted hererocycloalkyl group bonded through a sulfide bond and having 3 to 30 carbon atoms, a substituted or an unsubstituted alkenyl group bonded through a sulfide bond and having 2 to 30 carbon atoms, or a substituted or an unsubstituted alkynyl group bonded through a sulfide bond and having 2 to 30 carbon atoms, if n is 1 or 2, at least two of R¹¹ to R¹⁶ are thiol groups, and at least one of R¹¹ to R¹⁶ is a substituted or an unsubstituted alkyl group bonded through a sulfide bond and having 1 to 30 carbon atoms, a substituted or an unsubstituted aryl group bonded through a sulfide bond and having 6 to 30 carbon atoms, a substituted or an unsubstituted heteroaryl group bonded through a sulfide bond and having 3 to 30 carbon atoms, a substituted or an unsubstituted cycloalkyl group bonded through a sulfide bond and having 3 to 30 carbon atoms, a substituted or an unsubstituted hererocycloalkyl group bonded through a sulfide bond and having 3 to 30 carbon atoms, a substituted or an unsubstituted alkenyl group bonded through a sulfide bond and having 2 to 30 carbon atoms, or a substituted or an unsubstituted alkynyl group bonded through a sulfide bond and having 2 to 30 carbon atoms.

10. The nanoparticle-containing film according to claim 1,
wherein the ligand is a monomer represented by a general formula (3) below 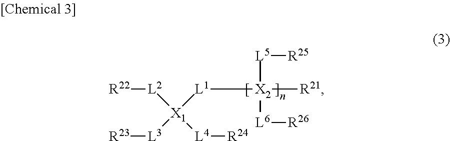
and
wherein in the general formula (3), X¹ and X² each independently represent a carbon atom, a substituted or an unsubstituted arylene group having 6 to 30 carbon atoms, a substituted or an unsubstituted heteroarylene group having 6 to 30 carbon atoms, a substituted or an unsubstituted cycloalkylene group having 3 to 30 carbon atoms, or a substituted or an unsubstituted heterocycloalkyl group having 3 to 30 carbon atoms, L¹ to L⁶ each independently represent either an alkylene group having 1 to 30 carbon atoms, or an alkenylene group having 2 to 30 carbon atoms, in which a single bond, a substituted, or an unsubstituted alkylene group having 1 to 30 carbon atoms, a substituted or an unsubstituted alkenylene group having 2 to 30 carbon atoms, or at least one methylene group that is not adjacent to each other is substituted with a substituent selected from a sulfonyl group, a carbonyl group, an ether group, a sulfide group, a sulfoxide group, an ester group, a —C(═O) NRa— group, a —NRb— group, and a combination thereof, Ra and Rb each independently represent a hydrogen atom or an alkyl group having 1 to 30 carbon atoms, R²¹ to R²⁶ each independently represent a hydrogen atom, a thiol group, a substituted or an unsubstituted alkyl group having 1 to 30 carbon atoms, a substituted or an unsubstituted aryl group having 6 to 30 carbon atoms, a substituted or an unsubstituted heteroaryl group having 3 to 30 carbon atoms, a substituted or an unsubstituted cycloalkyl group having 3 to 30 carbon atoms, a substituted or an unsubstituted heterocycloalkyl group having 3 to 30 carbon atoms, a substituted or an unsubstituted alkenyl group having 2 to 30 carbon atoms, a substituted or an unsubstituted alkynyl group having 2 to 30 carbon atoms, an epoxy-based compound residue bonded through a sulfide bond, an oxazoline-based compound residue bonded through a sulfide bond, or a nitrile-based compound residue bonded through a sulfide bond, n represents an integer of 0 to 2, if n is 0, at least three of R²¹ to R²⁴ are thiol groups, and at least one of R²¹ to R²⁴ is an epoxy-based compound residue bonded through a sulfide bond, an oxazoline-based compound residue bonded through a sulfide bond, or a nitrile-based compound residue bonded through a sulfide bond, if n is 1 or 2, at least two of R²¹ to R²⁶ are thiol groups, and at least one of R²¹ to R²⁶ is an epoxy-based compound residue bonded through a sulfide bond, an oxazoline-based compound residue bonded through a sulfide bond, or a nitrile-based compound residue bonded through a sulfide bond

11. The nanoparticle-containing film according to claim 10,
wherein, in the general formula (3), if n is 0, at least one of R²¹ to R²⁴ is an epoxy-based compound residue bonded through a sulfide bond, or an oxazoline-based compound residue bonded through a sulfide bond, the at least one of R²¹ to R²⁴ contains: a sulfide bond; and either a hydroxy group, or an amide group, if n is 1 or 2, at least one of R²¹ to R²⁶ is an epoxy-based compound residue bonded through a sulfide bond, or an oxazoline-based compound residue bonded through a sulfide bond, and the at least one of R²¹ to R²⁶ contains: a sulfide bond; and either a hydroxy group, or an amide group.

12. The nanoparticle-containing film according to claim 10,
wherein the epoxy-based compound residue bonded through the sulfide bond is a group represented by a general formula (4) below 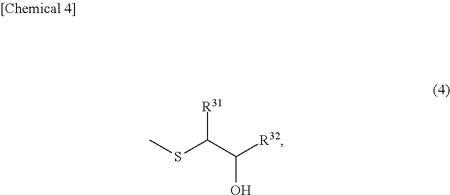
wherein R³¹ and R³² each independently represent a hydrogen atom or a monovalent organic residue,
the oxazoline-based compound residue bonded through the sulfide bond is a group represented by a general formula (5) below 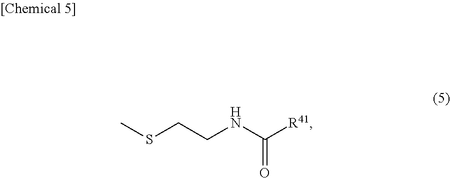
and
wherein R⁴¹ represents a hydrogen atom or a monovalent organic residue.

13. A light-emitting element, comprising:
a first electrode;
a second electrode; and
the nanoparticle-containing film, according to claim 1, disposed between the first electrode and the second electrode.

14. The light-emitting element according to claim 13,
wherein the nanoparticles are quantum dots, and
the nanoparticle-containing film is a light-emitting layer.

15. The light-emitting element according to claim 13,
wherein the nanoparticles are inorganic nanoparticles capable of transporting carriers, and
the nanoparticle-containing film is a carrier transport layer.

16. A production method for the nanoparticle-containing film according to claim 1, the production method comprising:
a nanoparticle film depositing step of depositing a nanoparticle film containing the plurality of nanoparticles, but not containing the ligand;
a first monomer supplying step of supplying the nanoparticle film with a first monomer having at least three thiol groups;
a second monomer supplying step of supplying, after the first monomer supplying step, the nanoparticle film with a second monomer having one functional group that reacts with a thiol group; and
a ligand forming step of forming, after the second monomer supplying step, the ligand by condensation of the first monomer and the second monomer in the nanoparticle film.

17. The production method for the nanoparticle-containing film according to claim 16,
wherein, at the ligand forming step, the nanoparticle film supplied with the first monomer and the second monomer is at least heat-treated or UV-treated, so that the first monomer and the second monomer are condensed.

18. The production method for the nanoparticle-containing film according to claim 16,
wherein the second monomer is one monomer selected from the group consisting of: an epoxy-based compound; an oxazoline-based compound; and a nitrile-based compound.

19. The production method for the nanoparticle-containing film according to claim 16,
wherein, at the first monomer supplying step, a first monomer solution, in which the first monomer is dispersed in a solvent, is applied to the nanoparticle film.

20. The production method for the nanoparticle-containing film according to claim 16,
wherein the first monomer is represented by a general formula (1) below 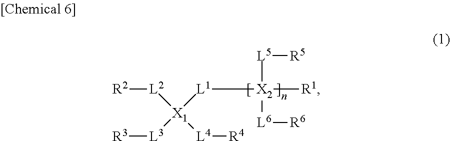
and
wherein, in the general formula (1), X¹ and X² each independently represent a carbon atom, a substituted or an unsubstituted arylene group having 6 to 30 carbon atoms, a substituted or an unsubstituted heteroarylene group having 6 to 30 carbon atoms, a substituted or an unsubstituted cycloalkylene group having 3 to 30 carbon atoms, or a substituted or an unsubstituted heterocycloalkyl group having 3 to 30 carbon atoms, L¹ to L⁶ each independently represent either an alkylene group having 1 to 30 carbon atoms, or an alkenylene group having 2 to 30 carbon atoms, in which a single bond, a substituted, or an unsubstituted alkylene group having 1 to 30 carbon atoms, a substituted or an unsubstituted alkenylene group having 2 to 30 carbon atoms, or at least one methylene group that is not adjacent to each other is substituted with a substituent selected from a sulfonyl group, a carbonyl group, an ether group, a sulfide group, a sulfoxide group, an ester group, a —C(═O) NRa— group, a —NRb— group, and a combination thereof, Ra and Rb each independently represent a hydrogen atom or an alkyl group having 1 to 30 carbon atoms, R¹ to R⁶ each independently represent a hydrogen atom, a thiol group, a substituted or an unsubstituted alkyl group having 1 to 30 carbon atoms, a substituted or an unsubstituted aryl group having 6 to 30 carbon atoms, a substituted or an unsubstituted heteroaryl group having 3 to 30 carbon atoms, a substituted or an unsubstituted cycloalkyl group having 3 to 30 carbon atoms, a substituted or an unsubstituted heterocycloalkyl group having 3 to 30 carbon atoms, a substituted or an unsubstituted alkenyl group having 2 to 30 carbon atoms, or a substituted or an unsubstituted alkynyl group having 2 to 30 carbon atoms, n represents an integer of 0 to 2, if n is 0, at least three of R¹ to R⁴ are thiol groups, and if n is 1 or 2, at least three of R¹ to R⁶ are thiol groups.
